(19) United States
(12) Patent Application Publication
(10) Pub. No.: US 2024/0365535 A1
(43) Pub. Date: Oct. 31, 2024

(54) SEMICONDUCTOR DEVICE AND METHOD OF FABRICATING THE SAME

(71) Applicant: SAMSUNG ELECTRONICS CO, LTD., Suwon-si (KR)

(72) Inventors: Jongmin KIM, Suwon-si (KR); Kiseok LEE, Suwon-si (KR); Bongsoo KIM, Suwon-si (KR); Chan-Sic YOON, Suwon-si (KR)

(21) Appl. No.: 18/397,014

(22) Filed: Dec. 27, 2023

(30) Foreign Application Priority Data
Apr. 25, 2023 (KR) 10-2023-0053980

(51) Int. Cl. H10B 12/00

(52) U.S. Cl. CPC H10B 12/488; H10B 12/315; H10B 12/482; H10B 12/485

(57) ABSTRACT

A semiconductor device includes a first active pattern including a first edge portion and a second edge portion, which are spaced apart from each other in a first direction; a first word line between the first edge portion of the first active pattern and the second edge portion of the first active pattern and extending in a second direction that crosses the first direction; a bit line on the first edge portion of the first active pattern and extending in a third direction that crosses the first direction and the second direction; and a storage node contact on the second edge portion of the first active pattern, wherein a top surface of the first edge portion is at a level higher than a top surface of the second edge portion.

### CROSS-REFERENCE TO RELATED APPLICATIONS

This U.S. non-provisional patent application claims priority under 35 U.S.C. § 119 to Korean Patent Application No. 10-2023-0053980, filed on Apr. 25, 2023, in the Korean Intellectual Property Office, the entire contents of which are hereby incorporated by reference.

### BACKGROUND

### 1. Field

Embodiments relate to a semiconductor device and a method of fabricating the same.

### 2. Description of the Related Art

Due to their small-sized, multifunctional, and/or low-cost characteristics, semiconductor devices are being considered as important elements in the electronic industry. The semiconductor devices are may be into a semiconductor memory device for storing data, a semiconductor logic device for processing data, and a hybrid semiconductor device including both memory and logic elements.

### SUMMARY

The embodiments may be realized by providing a semiconductor device including a first active pattern including a first edge portion and a second edge portion, which are spaced apart from each other in a first direction; a first word line between the first edge portion of the first active pattern and the second edge portion of the first active pattern and extending in a second direction that crosses the first direction; a bit line on the first edge portion of the first active pattern and extending in a third direction that crosses the first direction and the second direction; and a storage node contact on the second edge portion of the first active pattern, wherein a top surface of the first edge portion is at a level higher than a top surface of the second edge portion.

The embodiments may be realized by providing a semiconductor device including a first active pattern including a first edge portion and a second edge portion, which are spaced apart from each other in a first direction; a first word line between the first edge portion of the first active pattern and the second edge portion of the first active pattern and extending in a second direction that crosses the first direction; a first bit line on the first edge portion of the first active pattern and extending in a third direction that crosses the first and second directions; and a storage node contact on the second edge portion of the first active pattern, wherein the first bit line is offset from the second edge portion in the second direction, and at a level higher than the second edge portion of the first active pattern.

The embodiments may be realized by providing a semiconductor device including an active pattern including a first edge portion and a second edge portion, which are spaced apart from each other in a first direction; a word line between the first edge portion of the active pattern and the second edge portion of the active pattern and extending in a second direction that crosses the first direction; a bit line on the first edge portion of the active pattern and extending in a third direction that crosses the first and second directions; and a storage node contact on the second edge portion of the active pattern, wherein the bit line is in contact with the first edge portion of the active pattern.

### BRIEF DESCRIPTION OF THE DRAWINGS

Features will be apparent to those of skill in the art by describing in detail exemplary embodiments with reference to the attached drawings in which:

FIG. 1A is a plan view illustrating a semiconductor device according to an embodiment.

FIG. 1B is an enlarged plan view illustrating a portion of the semiconductor device of FIG. 1A.

FIGS. 2A to 2D are sectional views corresponding to lines A-A′, B-B′, C-C′, and D-D′ of FIG. 1A, respectively.

FIGS. 3A to 3E are plan views, each of which illustrates a semiconductor device according to an embodiment.

FIGS. 4A and 4B are sectional views corresponding to the lines A-A′ and B-B′ of FIG. 1A, respectively.

FIGS. 5A and 5B are sectional views corresponding to the lines B-B′ and C-C′ of FIG. 1A, respectively.

FIGS. 6A and 6B are sectional views corresponding to the lines A-A′ and B-B′ of FIG. 1A, respectively.

FIG. 7 is a sectional view corresponding to the line A-A′ of FIG. 1A.

FIGS. 8 to 21D are diagrams of stages in a method of fabricating a semiconductor device, according to an embodiment.

FIGS. 22 to 25D are diagrams of stages in a method of fabricating a semiconductor device, according to an embodiment.

### DETAILED DESCRIPTION

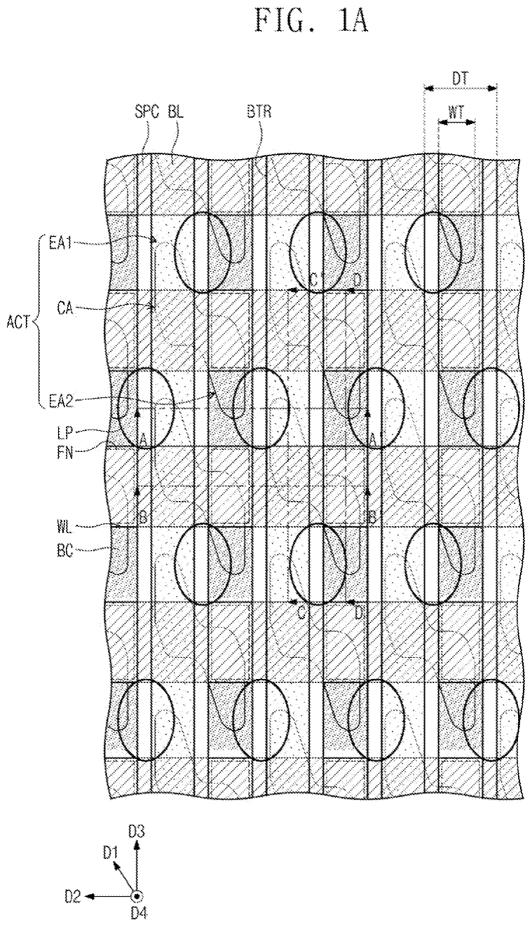

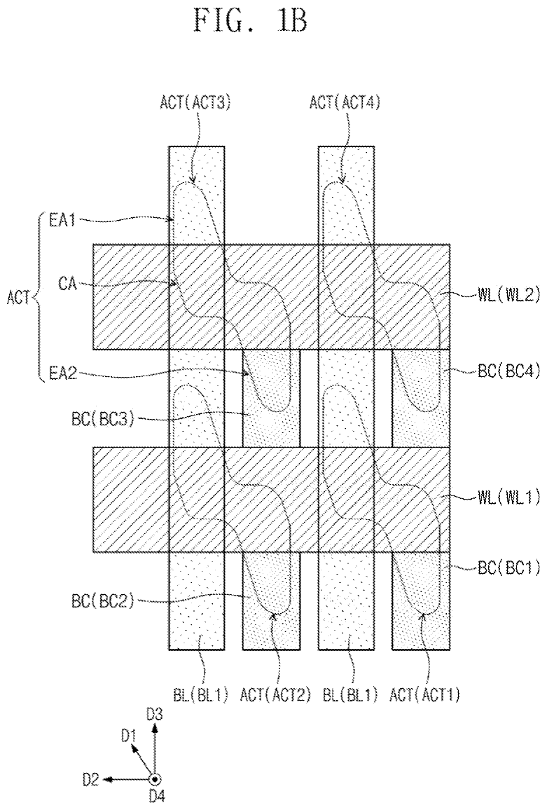

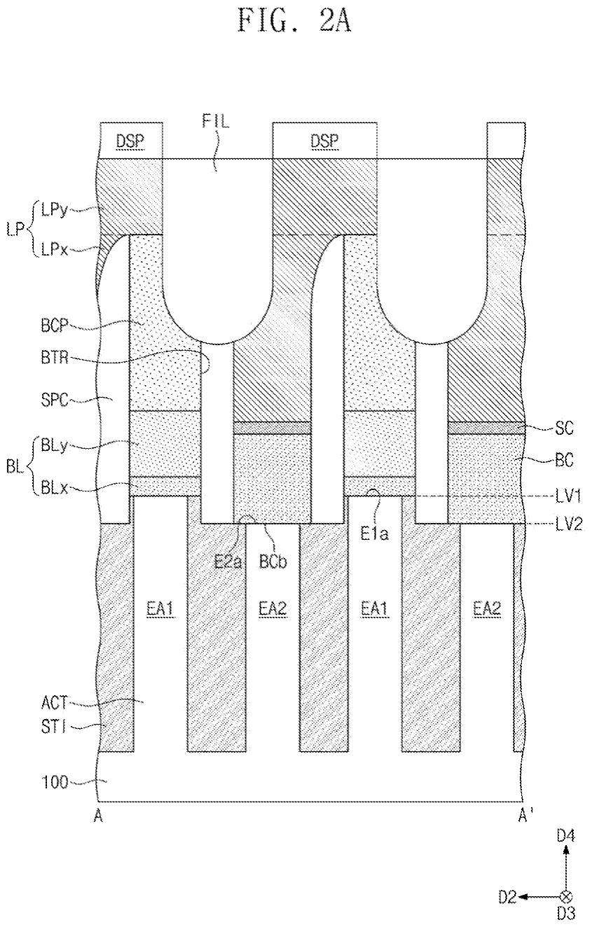

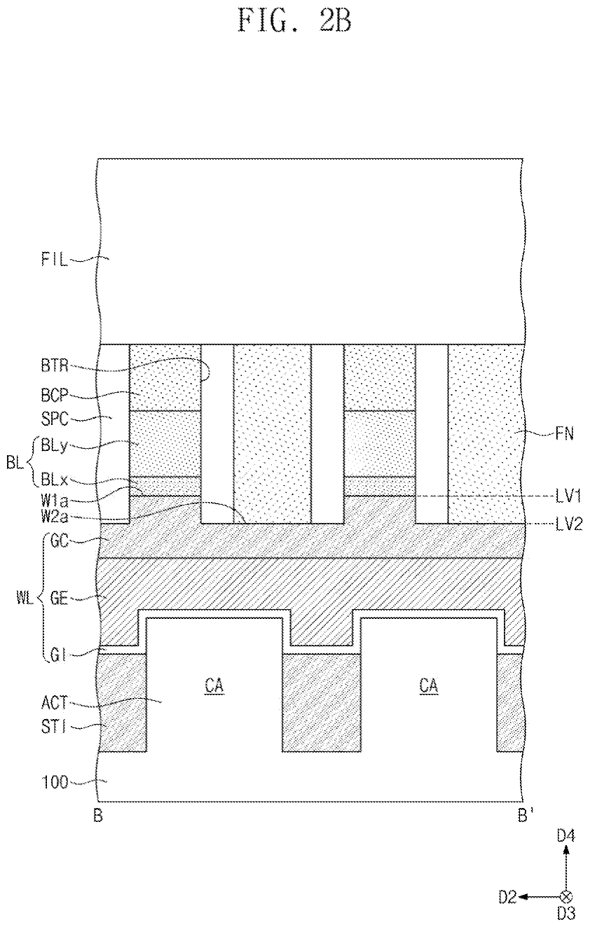

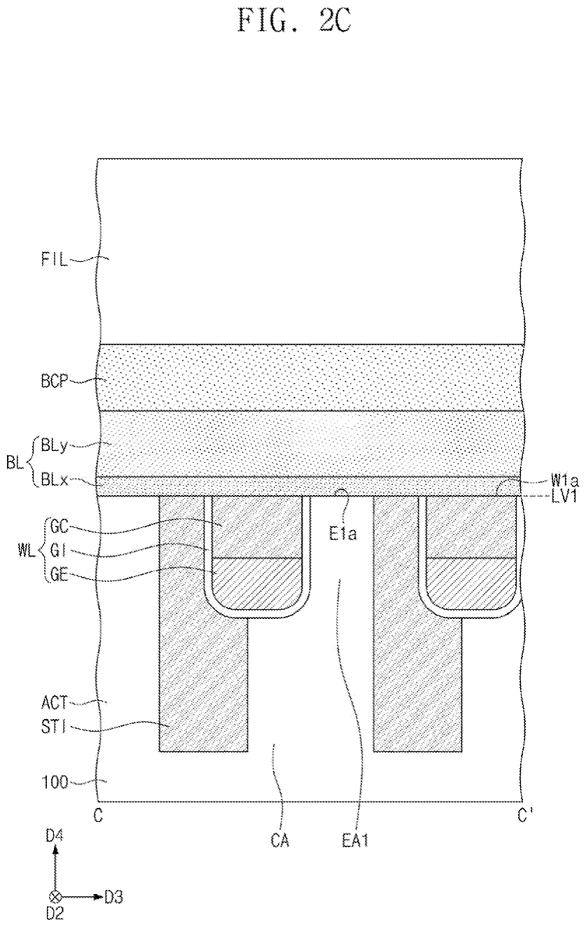

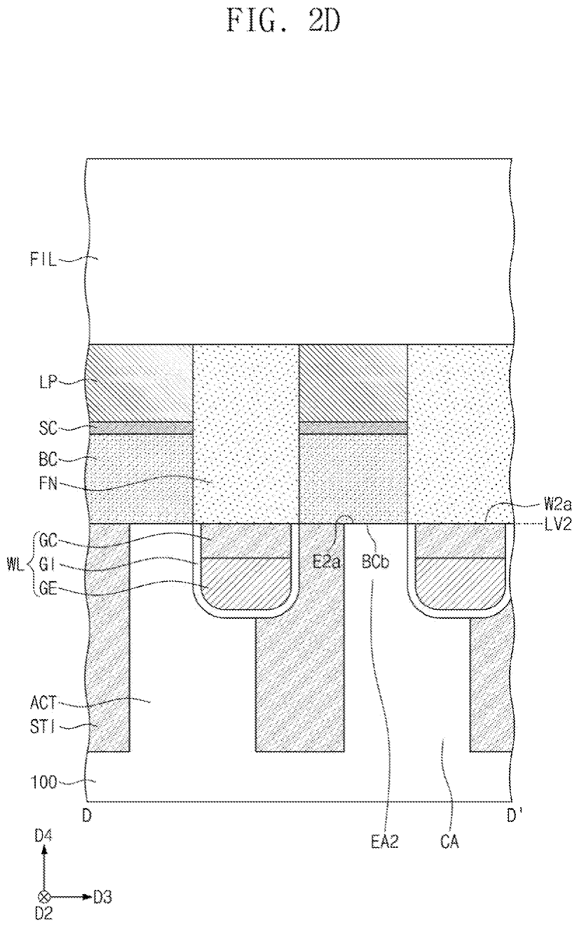

FIG. 1A is a plan view illustrating a semiconductor device according to an embodiment. FIG. 1B is an enlarged plan view illustrating a portion of the semiconductor device of FIG. 1A. FIGS. 2A to 2D are sectional views corresponding to lines A-A′, B-B′, C-C′, and D-D′ of FIG. 1A, respectively.

Referring to FIGS. 1 and 2A to 2D, a substrate 100 may be provided. The substrate 100 may be a semiconductor substrate (e.g., a silicon wafer, a germanium wafer, or a silicon-germanium wafer). As used herein, the term “or” is not necessarily an exclusive term, e.g., “A or B” would include A, B, or A and B.

A device isolation pattern STI may be in the substrate 100 to define an active pattern ACT. In an implementation, a plurality of active patterns ACT may be provided. The active patterns ACT may include portions of the substrate 100 enclosed by the device isolation pattern STI. In the present specification, for the sake of convenience in explanation, the term “substrate 100” may refer to the remaining portion of the substrate 100, excluding the afore-described portions of the substrate 100, unless otherwise stated.

Each of the active patterns ACT may be a patten that is elongated in a first direction D1 parallel to a bottom surface of the substrate 100. The active patterns ACT may be spaced apart from each other in a second direction D2 and a third direction D3, which are parallel to the bottom surface of the substrate 100 and are non-parallel to each other. The first to third directions D1, D2, and D3 may not be parallel to each other. The active patterns ACT may have a shape protruding in a (e.g., vertical) fourth direction D4 perpendicular to the bottom surface of the substrate 100. The active pattern ACT may be formed of or include silicon (e.g., single-crystalline silicon).

The active pattern ACT may include a first edge portion EA1 and a second edge portion EA2, which may be spaced apart from each other in the first direction D1, and a center portion CA therebetween. The first and second edge portions EA1 and EA2 may be end portions of the active pattern ACT, which are opposite to each other in the first direction D1. The center portion CA may be below a word line WL, which may cross the active pattern ACT and will be described below. The word line WL may be vertically overlapped with the center portion CA of the active pattern ACT. The center portions CA of the active patterns ACT may be spaced apart from each other in the second and third directions D2 and D3. As used herein, the terms “first,” “second,” and the like are merely for identification and differentiation, and are not intended to imply or require sequential inclusion (e.g., a third element and a fourth element may be described without implying or requiring the presence of a first element or second element).

A top surface Ela of the first edge portion EA1 and a top surface E2a of the second edge portion EA2 may be located at different levels from each other (e.g., different distances from the substrate 100 in the fourth direction D4). The top surface Ela of the first edge portion EA1 may be at a first level LV1. The top surface E2a of the second edge portion EA2 may be at a second level LV2. The first level LV1 may be higher (e.g., farther from the substrate 100 in the fourth direction D4) than the second level LV2. In an implementation, the top surface Ela of the first edge portion EA1 may be at a level higher than the top surface E2a of the second edge portion EA2.

Each of the first and second edge portions EA1 and EA2 and the center portion CA may include impurity regions that are doped with impurities (e.g., n- or p-type impurities). The impurity region may be used as one of source, drain, and channel regions of a transistor.

The active patterns ACT, which are adjacent to each other, may be side by side in one of the second and third directions D2 and D3 or opposite directions of them. In the present specification, the description of adjacent ones of the active patterns ACT are disposed side by side in a specific direction may mean that the first edge portions EA1 of adjacent ones of the active patterns ACT are disposed in the specific direction.

Referring to FIG. 1B, a first active pattern ACT1, a second active pattern ACT2, a third active pattern ACT3, and a fourth active pattern ACT4 may be disposed in a clockwise direction. The first and second active patterns ACT1 and ACT2, which may be adjacent to each other, may be side by side in the second direction D2. The fourth and third active patterns ACT4 and ACT3, which may be adjacent to each other, may be side by side in the second direction D2. The first and fourth active patterns ACT1 and ACT4, which may be adjacent to each other, may be side by side in the third direction D3. The second and third active patterns ACT2 and ACT3, which may be adjacent to each other, may be side by side in the third direction D3.

The second edge portion EA2 of the fourth active pattern ACT4, the first edge portion EA1 of the first active pattern ACT1, the second edge portion EA2 of the third active pattern ACT3, and the first edge portion EA1 of the second active pattern ACT2 may be sequentially disposed in or along the second direction D2. The first edge portion EA1 of the first active pattern ACT1 may be between the second edge portion EA2 of the fourth active pattern ACT4 and the second edge portion EA2 of the third active pattern ACT3. The second edge portion EA2 of the third active pattern ACT3 may be between the first edge portion EA1 of the first active pattern ACT1 and the first edge portion EA1 of the second active pattern ACT2.

In an implementation, the active patterns ACT may be side by side in one of the second and third directions D2 and D3 and opposite directions of them, and this may make it possible to simplify the disposition of elements in the semiconductor device. Accordingly, it may be possible to reduce a process difficulty in a patterning process, which may be performed to fabricate a semiconductor device, and consequently to easily fabricate the semiconductor device. In an implementation, the elements may be disposed in a relatively simple manner, and an integration density of the semiconductor device may also be increased.

Referring back to FIGS. 1 and 2A to 2D, the device isolation pattern STI may be formed of or include an insulating material (e.g., silicon oxide (SiO₂) or silicon nitride (SiN)). The device isolation pattern STI may be a single layer, which is made of a single material, or a composite layer including two or more materials.

The word line WL may cross the active patterns ACT and the device isolation pattern STI. In an implementation, a plurality of word lines WL may be provided. The word lines WL may extend (e.g., lengthwise) in the second direction D2 and may be spaced apart from each other in the third direction D3. The word line WL may be on the center portion CA of the active pattern ACT and between the first and second edge portions EA1 and EA2. The center portion CA of the active pattern ACT may be a portion of the active pattern ACT placed below the word line WL. The first edge portion EA1 of the active pattern ACT may be another portion of the active pattern ACT protruding from the word line WL in the third direction D3. The second edge portion EA2 of the active pattern ACT may be the other portion of the active pattern ACT protruding from the word line WL in an opposite direction of the third direction D3. In an implementation, each of the word lines WL may be on the center portions CA of the active patterns ACT, which are arranged side by side in the second direction D2, and may extend in the second direction D2.

Each of the word lines WL may include a gate electrode GE, a gate dielectric pattern GI, and a gate capping pattern GC. The gate electrode GE may penetrate the active patterns ACT and the device isolation pattern STI in the second direction D2. The gate dielectric pattern GI may be between the gate electrode GE and the active patterns ACT and between the gate electrode GE and the device isolation pattern STI. The gate capping pattern GC may be on the gate electrode GE to cover a top surface of the gate electrode GE. In an implementation, the gate electrode GE may include a conductive material. In an implementation, the gate electrode GE may be a single layer, which is made of a single material, or a composite layer including two or more materials. The gate dielectric pattern GI may be formed of or include silicon oxide (SiO₂) or high-k dielectric materials. In the present specification, the high-k dielectric material may be defined as a material having a dielectric constant higher than that of silicon oxide. In an implementation, the gate capping pattern GC may be formed of or include silicon nitride (SiN).

The word line WL may have a first top surface W1a and a second top surface W2a, which may be at different levels from each other. The first top surface W1a of the word line WL may be below a bit line BL to be described below, and the second top surface W2a may be below a fence pattern FN to be described below. The first top surface W1a of the word line WL may be at a level higher than the second top surface W2a. In an implementation, the first top surface W1a of the word line WL may be at substantially the same level as the first level LV1. The second top surface W2a of the word line WL may be at a level that is substantially equal to or lower than the second level LV2.

Referring to FIG. 1B, a first word line WL1 and a second word line WL2 may be spaced apart from each other in the third direction D3. The first word line WL1 may be on the center portion CA of the first active pattern ACT1 and the center portion CA of the second active pattern ACT2 and may extend in the second direction D2. The second word line WL2 may be on the center portion CA of the fourth active pattern ACT4 and the center portion CA of the third active pattern ACT3 and may extend in the second direction D2. The second edge portion EA2 of the fourth active pattern ACT4, the first edge portion EA1 of the first active pattern ACT1, the second edge portion EA2 of the third active pattern ACT3, and the first edge portion EA1 of the second active pattern ACT2 may be sequentially disposed in the second direction D2, between the first and second word lines WL1 and WL2.

Referring back to FIGS. 1 and 2A to 2D, the bit line BL may be on the first edge portion EA1 of the active pattern ACT. In an implementation, the bit line BL may be in contact (e.g., direct contact) with the first edge portion EA1 of the active pattern ACT. The bit line BL may be electrically connected to the first edge portion EA1 of the active pattern ACT. The bit line BL may be in direct contact with the first edge portion EA1 without any contact, and a contact resistance between the bit line BL and the first edge portion EA1 may be improved. As a result, the electric characteristics of the semiconductor device may be improved. In an implementation, the bit line BL may fully cover the top surface Ela of the first edge portion EA1.

The bit line BL may be spaced apart from the second edge portion EA2 of the active pattern ACT. The bit line BL may be at a level higher than the second edge portion EA2 of the active pattern ACT. The bit line BL may be offset from the second edge portion EA2 in the second direction D2. The bit line BL may not be vertically overlapped with the second edge portion EA2.

In an implementation, a plurality of bit lines BL may be provided. The bit lines BL may be spaced apart from each other in the second direction D2 and may be extended in the third direction D3. Each of the bit lines BL may be on the first edge portions EA1 of the active patterns ACT, which may be arranged in the third direction D3 to form a single column. In an implementation, each of the bit lines BL may be in contact with the column of the first edge portions EA1 of the active patterns ACT. A bottom surface of the bit line BL may be at a level higher than the top surface E2a of the second edge portion EA2 of the active pattern ACT.

The bit line BL may be a composite layer including two or more materials. In an implementation, the bit line BL may include a lower bit line BLx and an upper bit line BLy. The upper bit line BLy may extend in the third direction D3. The lower bit line BLx may be between the first edge portion EA1 of the active pattern ACT and the upper bit line BLy. In an implementation, the lower bit line BLx may extend in the third direction D3, between the first edge portion EA1 of the active pattern ACT and the upper bit line BLy.

The lower bit line BLx may include a first barrier pattern (e.g., to help prevent the diffusion of the material of the upper bit line Bly) or a first silicide pattern (e.g., to help improve a contact resistance between the upper bit line BLy and the first edge portion EA1). In an implementation, the lower bit line BLx may be formed of or include a metal silicide material (e.g., silicide materials containing Ti, Mo, W, Cu, Al, Ta, Ru, Ir, or Co) or a metal nitride material (e.g., nitride materials containing Ti, Mo, W, Cu, Al, Ta, Ru, Ir, or Co). The upper bit line Bly may be formed of or include a metallic material (e.g., Ti, Mo, W, Cu, Al, Ta, Ru, Ir, or Co).

Referring to FIG. 1B, a first bit line BL1 and a second bit line BL2 may be spaced apart from each other in the second direction D2. The first bit line BL1 may be on the first edge portion EA1 of the first active pattern ACT1 and the first edge portion EA1 of the fourth active pattern ACT4 and may extend in the third direction D3. The second bit line BL2 may be on the first edge portion EA1 of the second active pattern ACT2 and the first edge portion EA1 of the third active pattern ACT3 and may extend in the third direction D3. When viewed in a plan view, the second edge portion EA2 of the second active pattern ACT2 and the second edge portion EA2 of the third active pattern ACT3 may be between the first bit line BL1 and the second bit line BL2.

Referring back to FIGS. 1 and 2A to 2D, a bit line capping pattern BCP may be on a top surface of the bit line BL. The bit line capping pattern BCP may extend in the third direction D3, along with the bit line BL. In an implementation, a plurality of bit line capping patterns BCP may be provided. The bit line capping patterns BCP may be spaced apart from each other in the second direction D2. The bit line capping pattern BCP may be vertically overlapped with the bit line BL. The bit line capping pattern BCP may be composed of a single layer or a plurality of layers. In an implementation, the bit line capping pattern BCP may include a first capping pattern, a second capping pattern, and a third capping pattern sequentially stacked. Each of the first to third capping patterns may be formed of or include silicon nitride (SiN). In an implementation, the bit line capping pattern BCP may include a plurality of capping patterns, which may be stacked to form four or more layers.

A bit line spacer SPC may be on a side surface of the bit line BL and a side surface of the bit line capping pattern BCP. The bit line spacer SPC may cover the side surface of the bit line BL and the side surface of the bit line capping pattern BCP. The bit line spacer SPC may extend along the side surface of the bit line BL and in the third direction D3. The bottommost portion of the bit line spacer SPC may be at a level that is lower than the first edge portion EA1 of the active pattern ACT or than the first level LV1. In an implementation, the bottommost end portion of the bit line spacer SPC may be at a level, which is equal to or higher than the second edge portion EA2 of the active pattern ACT or than the second level LV2.

In an implementation, the bit line spacer SPC may be formed of or include silicon oxide (SiO₂), silicon nitride (SiN), silicon oxycarbide (SiOC), or silicon oxycarbonitride (SiOCN). In an implementation, the bit line spacer SPC may further include an air gap therein. The bit line spacer SPC may be a single layer, which is made of a single material, or a composite layer including two or more materials. The bit line spacer SPC may include a plurality of sub-spacers (not shown), which are sequentially provided on the side surface of the bit line BL.

A bit line trench region BTR may be defined between the bit lines BL, which may be adjacent to each other in the second direction D2, and between the bit line capping patterns BCP, which may be adjacent to each other in the second direction D2. In an implementation, a plurality of bit line trench regions BTR may be provided. The bit line trench regions BTR may be spaced apart from each other in the second direction D2 and may be extended in the third direction D3.

The top surface E2a of the second edge portion EA2 of the active pattern ACT may constitute a portion of an inner bottom surface of the bit line trench region BTR. The bit line trench region BTR may be vertically overlapped with the second edge portion EA2 of the active pattern ACT. In an implementation, the bit line trench region BTR may be vertically overlapped with the entire region of the top surface E2a of the second edge portion EA2. In an implementation, the bit line trench region BTR may be vertically overlapped with the second edge portions EA2 of the active patterns ACT, which may be side by side in the third direction D3. When measured in the second direction D2, a distance DT between adjacent ones of the bit lines BL (i.e., a width of the bit line trench region BTR) may be larger than a width WT (e.g., the largest width) of the second edge portion EA2 of the active pattern ACT.

A storage node contact BC may be in the bit line trench region BTR. In an implementation, the storage node contact BC in the bit line trench region BTR may be between the bit line spacers SPC, which may be adjacent to each other in the second direction D2. The storage node contact BC may be on the top surface E2a of the second edge portion EA2 of the active pattern ACT. In an implementation, the storage node contact BC may fully cover the top surface E2a of the second edge portion EA2. The storage node contact BC may be spaced apart from the first edge portion EA1 of the active pattern ACT and the bit line BL with the bit line spacer SPC therebetween.

In an implementation, a plurality of storage node contacts BC may be provided. The storage node contacts BC may be spaced apart from each other in the second and third directions D2 and D3. The storage node contacts BC, which may be adjacent to each other in the second direction D2, may be spaced apart from each other with the bit line BL therebetween. The storage node contacts BC, which may be adjacent to each other in the third direction D3, may be spaced apart from each other with the fence pattern FN therebetween. The storage node contacts BC, which may be adjacent to each other in the third direction D3, may be in one bit line trench region BTR.

Each of the storage node contacts BC may be on a corresponding one of the second edge portions EA2 of the active patterns ACT. The storage node contact BC may be electrically connected to the second edge portion EA2. In an implementation, the storage node contact BC may be in direct contact with and electrically connected to the second edge portion EA2. In an implementation, the storage node contact BC may be electrically connected to the second edge portion EA2 through an additional contact pattern. A bottom BCb of the storage node contact BC may be at a level that is lower than the top surface Ela of the first edge portion EA1 of the active pattern ACT or than the first level LV1. In an implementation, the storage node contact BC may be formed of or include silicon (e.g., doped polysilicon) or a metallic material (e.g., Ti, Mo, W, Cu, Al, Ta, Ru, Ir, or Co).

Referring to FIG. 1B, a first storage node contact BC1, a second storage node contact BC2, a third storage node contact BC3, and a fourth storage node contact BC4 may be spaced apart from each other in the second and third directions D2 and D3. The first storage node contact BC1, the second storage node contact BC2, the third storage node contact BC3, and the fourth storage node contact BC4 may be disposed in a clockwise direction. The first storage node contact BC1, the second storage node contact BC2, the third storage node contact BC3, and the fourth storage node contact BC4 may be on the second edge portion EA2 of the first active pattern ACT1, the second edge portion EA2 of the second active pattern ACT2, the second edge portion EA2 of the third active pattern ACT3, and the second edge portion EA2 of the fourth active pattern ACT4, respectively. When viewed in a plan view, the third and fourth storage node contacts BC3 and BC4 may be between the first and second word lines WL1 and WL2. When viewed in a plan view, the second and third storage node contacts BC2 and BC3 may be between the first bit line BL1 and the second bit line BL2.

Referring back to FIGS. 1 and 2A to 2D, the fence pattern FN may be in the bit line trench region BTR. The fence pattern FN may be on the word line WL. In an implementation, the fence pattern FN may be between the bit line spacers SPC, which may be in the bit line trench region BTR and adjacent to each other in the second direction D2. A bottom surface of the fence pattern FN may be at a level that is equal to or lower than the second level LV2.

In an implementation, a plurality of fence patterns FN may be provided. The fence patterns FN may be spaced apart from each other in the second and third directions D2 and D3. The fence patterns FN, which may be adjacent to each other in the second direction D2, may be spaced apart from each other with the bit line BL therebetween. The fence patterns FN, which may be adjacent to each other in the third direction D3, may be spaced apart from each other with the storage node contact BC therebetween. The fence pattern FN may be formed of or include silicon oxide (SiO₂), silicon nitride (SiN), silicon oxycarbide (SiOC), or silicon oxycarbonitride (SiOCN).

A landing pad LP may be on the storage node contact BC. In an implementation, a plurality of landing pads LP may be provided. The landing pads LP may be spaced apart from each other in the second and third directions D2 and D3. Each of the landing pads LP may be electrically connected to a corresponding one of the second edge portions EA2 through a corresponding one of the storage node contacts BC. In an implementation, the landing pad LP may be formed of or include a metallic material (e.g., Ti, Mo, W, Cu, Al, Ta, Ru, Ir, or Co). In an implementation, a second silicide pattern SC may be further included between the landing pad LP and the storage node contact BC. In an implementation, a second barrier pattern may be between the landing pad LP and other elements and may help prevent the diffusion of the material of the landing pad LP.

The landing pad LP may include a lower landing pad LPx and an upper landing pad LPy. The lower landing pad LP may be in the bit line trench region BTR and may be vertically overlapped with the storage node contact BC. The upper landing pad LPy may be on the bit line capping pattern BCP and may be shifted from the lower landing pad LPx in the third direction D3 or an opposite direction thereof. The lower landing pad LPx and the upper landing pad LPy may be formed of or include the same material or different materials from each other.

A filling pattern FIL may enclose the landing pad LP. The filling pattern FIL may be between adjacent ones of the landing pads LP. When viewed in a plan view, the filling pattern FIL may have a mesh shape, in which a plurality of holes are formed, and the landing pads LP may fill the holes, respectively. The landing pads LP may penetrate the filling pattern FIL. In an implementation, the filling pattern FIL may be formed of or include silicon nitride (SiN), silicon oxide (SiO₂), or silicon oxynitride (SiON). In an implementation, the filling pattern FIL may include an empty space with an air layer (i.e., an air gap).

A data storage pattern DSP may be on the landing pad LP. In an implementation, a plurality of data storage patterns DSP may be provided. The data storage patterns DSP may be spaced apart from each other in the second and third directions D2 and D3. Each of the data storage patterns DSP may be electrically connected to a corresponding one of the second edge portions EA2 through a corresponding one of the landing pads LP and a corresponding one of the storage node contacts BC.

In an implementation, the data storage pattern DSP may be a capacitor including a bottom electrode, a dielectric layer, and a top electrode. In this case, the semiconductor memory device according to an embodiment may be a dynamic random access memory (DRAM) device. In an implementation, the data storage pattern DSP may include a magnetic tunnel junction pattern. In this case, the semiconductor memory device may be a magnetic random access memory (MRAM) device. In an implementation, the data storage pattern DSP may be formed of or include a phase-change material or a variable resistance material. In this case, the semiconductor memory device may be a phase-change random access memory (PRAM) device or a resistive random access memory (ReRAM) device. In an implementation, the data storage pattern DSP may include various other structures and/or materials which can be used to store data.

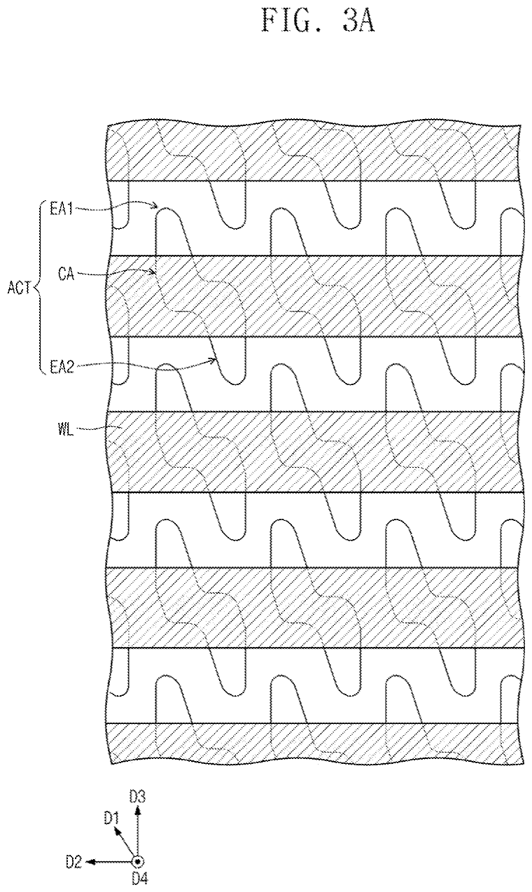

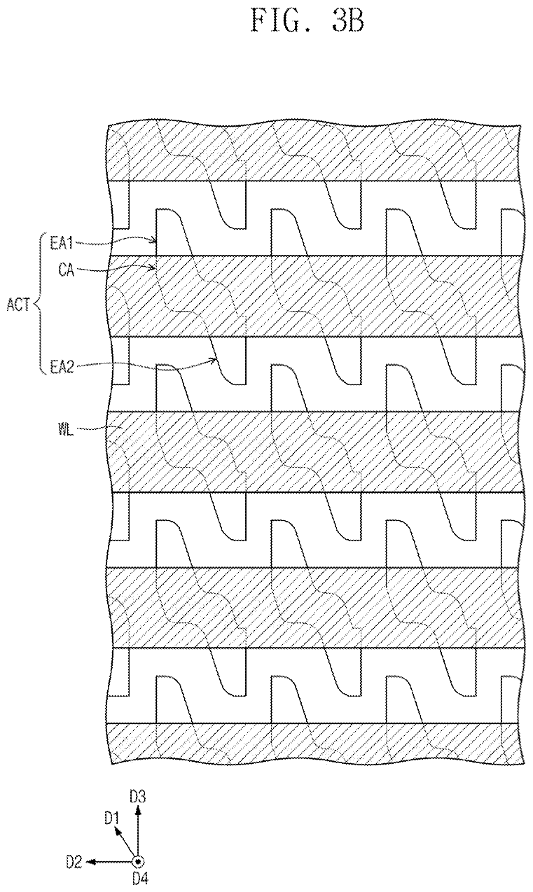

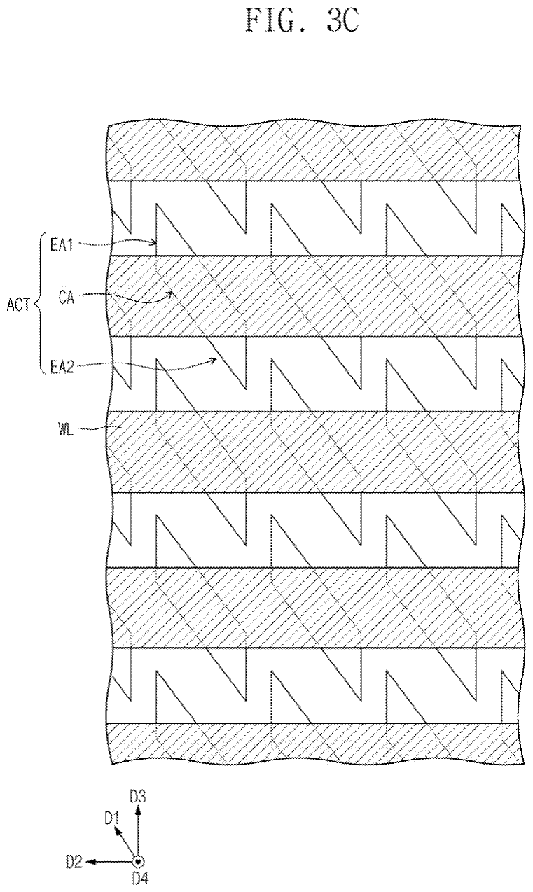

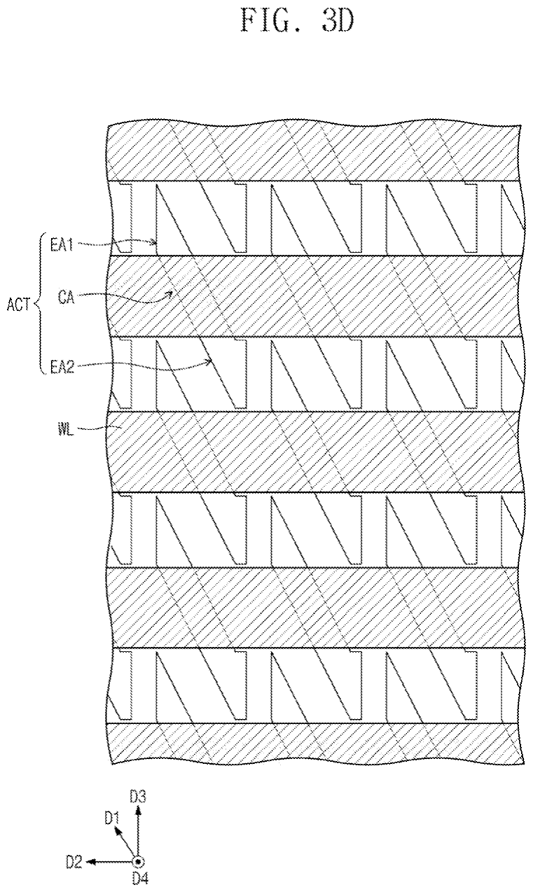

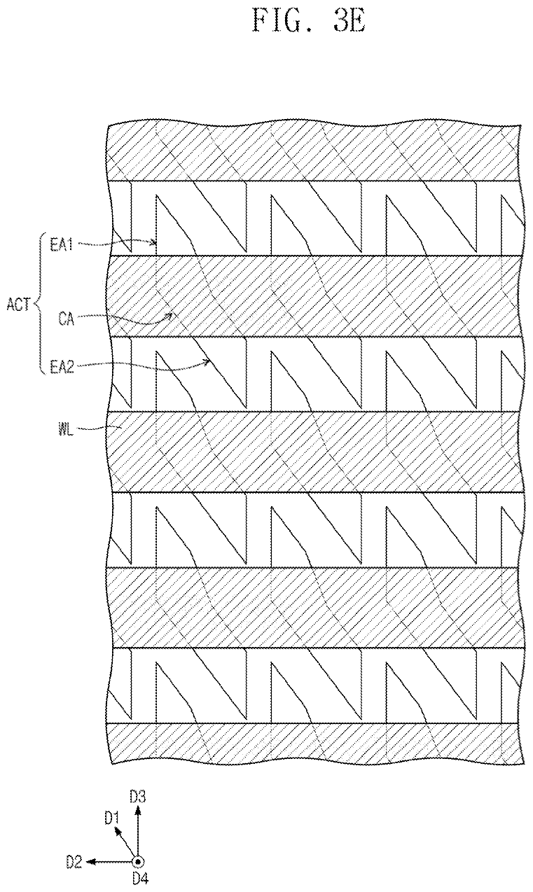

Hereinafter, a semiconductor device according to an embodiment will be described in more detail with reference to FIGS. 3A to 7. In the following description, a previously-described element may be identified by the same reference number without repeating an overlapping description thereof, for concise description.

FIGS. 3A to 3E are plan views, each of which illustrates a semiconductor device according to an embodiment.

Referring to FIGS. 3A to 3E, the active pattern ACT may have various profiles, when viewed in a plan view. The active patterns ACT may be spaced apart from each other in the second and third directions D2 and D3 and may have a profile that is elongated in the first direction D1. The first and second edge portions EA1 and EA2 of the active pattern ACT may be symmetric or asymmetric in shape with respect to the center portion CA.

Referring to FIG. 3A, the first and second edge portions EA1 and EA2 of the active pattern ACT may have a symmetrical profile with respect to the center portion CA. The first edge portion EA1 of the active pattern ACT may protrude from the word line WL in the third direction D3, and the second edge portion EA2 may protrude from the word line WL in an opposite direction of the third direction D3. Each of the first and second edge portions EA1 and EA2 may have a long axis, which extends in a direction between the first and third directions D1 and D3. The first edge portion EA1 may have the long axis, a contact area between the first edge portion EA1 and the bit line BL may be increased, and thus, a contact resistance therebetween may be improved. Similarly, the second edge portion EA2 may have the long axis, a contact area between the second edge portion EA2 and the storage node contact BC may be increased, and thus, a contact resistance therebetween may be improved.

Referring to FIG. 3B, the first and second edge portions EA1 and EA2 of the active pattern ACT may have an asymmetrical profile with respect to the center portion CA. The second edge portion EA2 of FIG. 3B may protrude further in an opposite direction of the second direction D2, when compared with the second edge portion EA2 of FIG. 3A. In this case, a contact area between the second edge portion EA2 and the storage node contact BC may be further increased, and as a result, a contact resistance therebetween may be improved. In an implementation, the first edge portion EA1 of FIG. 3B may protrude further in the second direction D2, when compared with the first edge portion EA1 of FIG. 3A.

Referring to FIG. 3C, the first and second edge portions EA1 and EA2 of the active pattern ACT may have a symmetrical profile with respect to the center portion CA. The active pattern ACT may have a long axis extending in the first direction D1. A side surface of the active pattern ACT may have a substantially line-shaped or linear profile. Thus, it may be possible to reduce technical difficulties in a process of patterning the active pattern ACT, and thus, the semiconductor device may be easily fabricated.

Referring to FIG. 3D, the first and second edge portions EA1 and EA2 of the active pattern ACT may have an asymmetrical profile with respect to the center portion CA. The second edge portion EA2 of FIG. 3D may protrude further in an opposite direction of the second direction D2, when compared with the second edge portion EA2 of FIG. 3C. In this case, a contact area between the second edge portion EA2 and the storage node contact BC may be further increased, and as a result, a contact resistance therebetween may be improved. In an implementation, the first edge portion EA1 of FIG. 3D may protrude further in the second direction D2, when compared with the first edge portion EA1 of FIG. 3C.

Referring to FIG. 3E, the first and second edge portions EA1 and EA2 of the active pattern ACT may have an asymmetrical profile with respect to the center portion CA. The first edge portion EA1 of FIG. 3E may protrude further in the third direction D3, when compared with the first edge portion EA1 of FIG. 3C. In this case, a contact area between the first edge portion EA1 and the bit line BL may be further increased, and as a result, a contact resistance therebetween may be improved. In an implementation, the second edge portion EA2 of FIG. 3E may protrude further in an opposite direction of the third direction D3, when compared with the second edge portion EA2 of FIG. 3C.

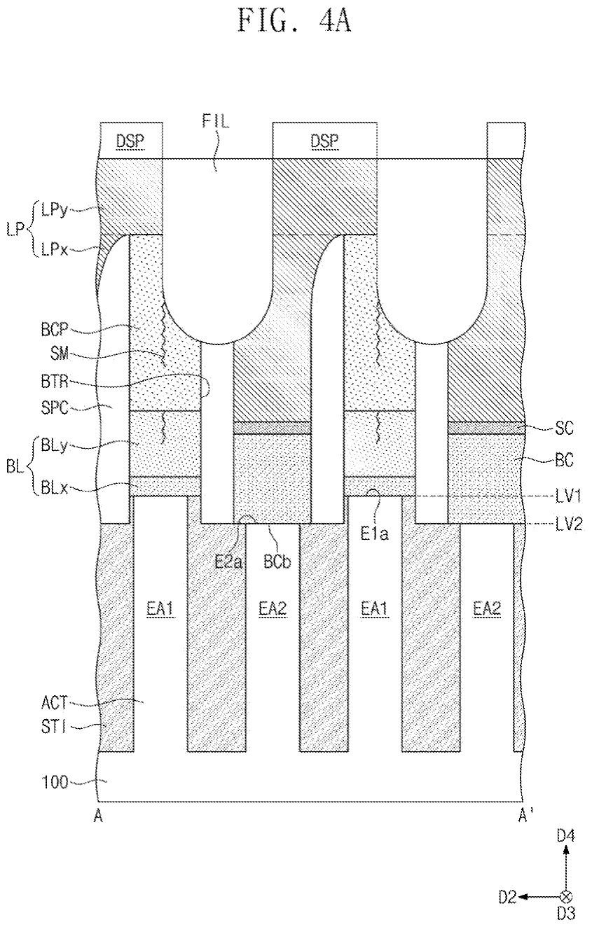

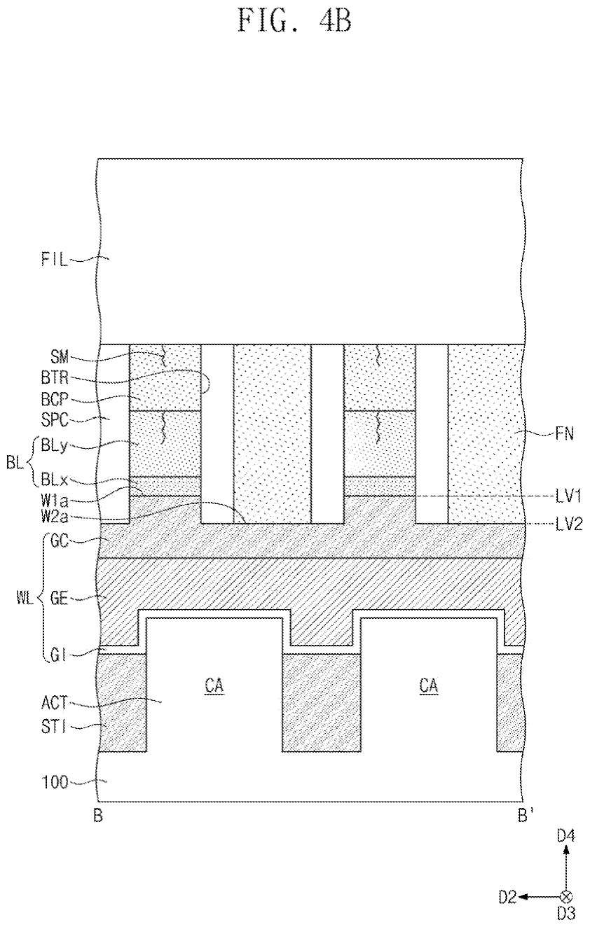

FIGS. 4A and 4B are sectional views corresponding to the lines A-A′ and B-B′ of FIG. 1A, respectively.

Referring to FIGS. 4A and 4B, at least one of the bit line BL and the bit line capping pattern BCP may include a seam SM therein. The seam SM may be selectively provided, depending on a fabrication process to be described below. The seam SM may be an unfilled space or a discontinuous interface which is formed when layers for the bit line BL and the bit line capping pattern BCP are deposited on opposite inner side surfaces of a mold trench region MTR to be described below. In an implementation, the seam SM may include an empty space or a void. The shape, position, and number of the seam SM may be variously changed.

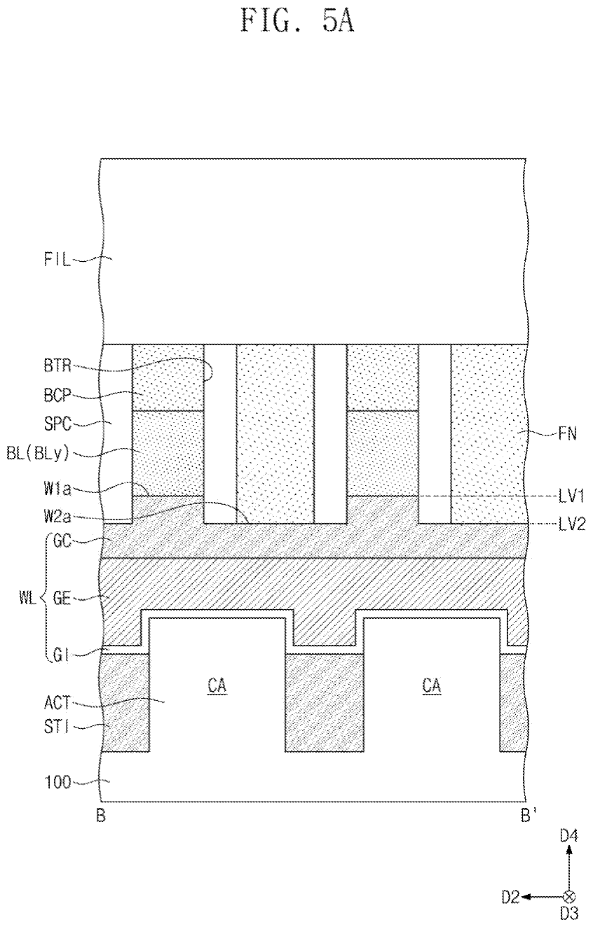

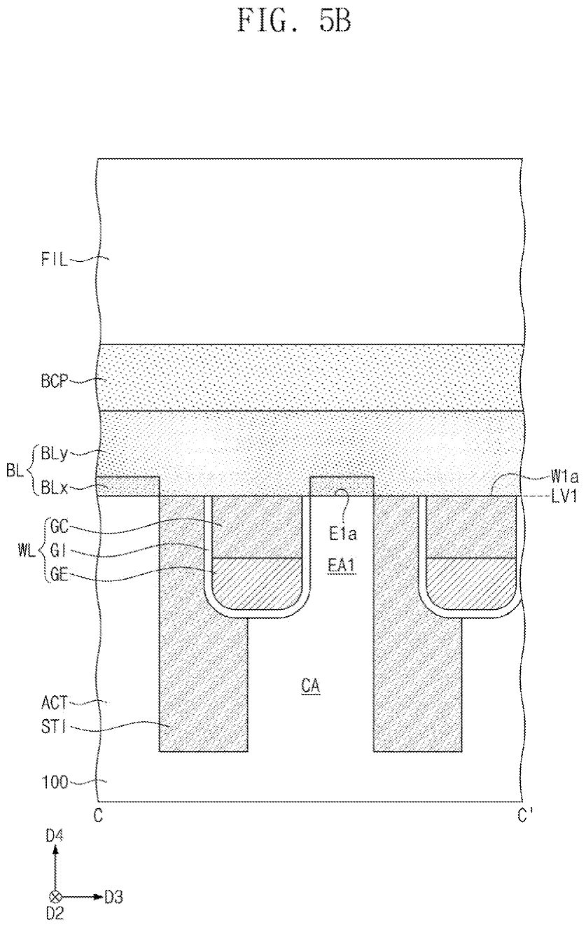

FIGS. 5A and 5B are sectional views corresponding to the lines B-B′ and C-C′ of FIG. 1A, respectively.

Referring to FIGS. 5A and 5B, the lower bit line BLx may be between the first edge portion EA1 of the active pattern ACT and the upper bit line BLy. The lower bit line BLx may be locally on the first edge portion EA1 of the active pattern ACT and may not be on the device isolation pattern STI and the word line WL. In an implementation, the lower bit line BLx may not be between the device isolation pattern STI and the upper bit line BLy and between the word line WL and the upper bit line BLy. The upper bit line BLy may be in contact with the device isolation pattern STI and the word line WL.

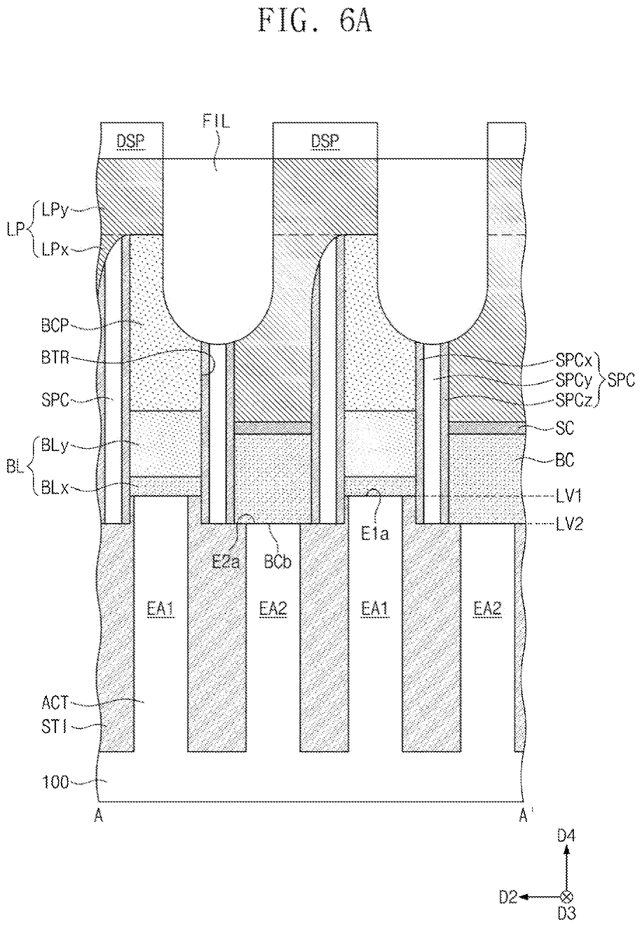

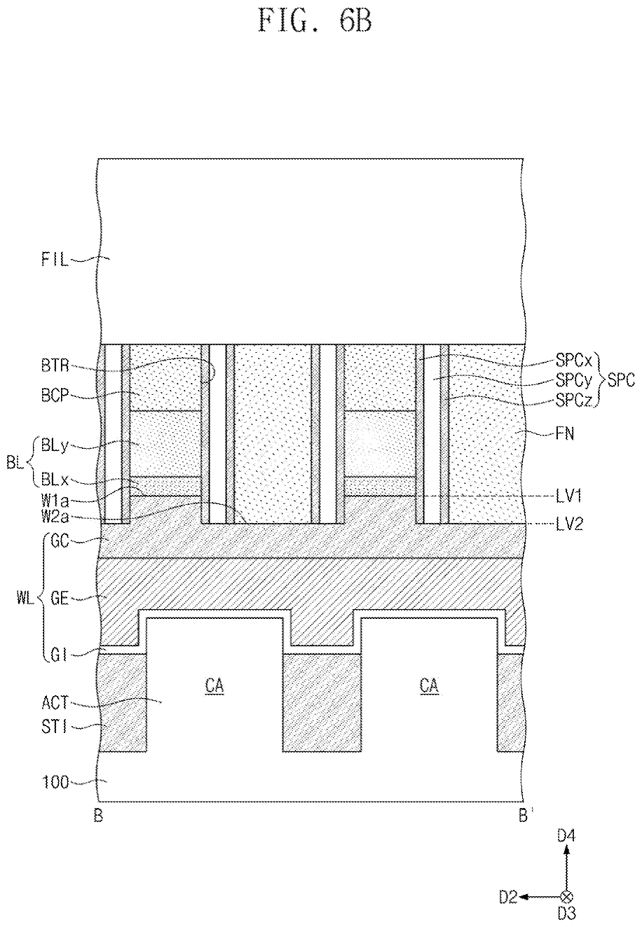

FIGS. 6A and 6B are sectional views corresponding to the lines A-A′ and B-B′ of FIG. 1A, respectively.

Referring to FIGS. 6A and 6B, the bit line spacer SPC may include a plurality of sub-spacers SPCx, SPCy, and SPCz. In an implementation, the bit line spacer SPC may include a first sub-spacer SPCx, a second sub-spacer SPCy, and a third sub-spacer SPCz, which may be sequentially on the side surface of the bit line BL. In an implementation, bottom ends of the sub-spacers SPCx, SPCy, and SPCz may be at the same level or different levels from each other. The lowermost one of the bottom ends of the sub-spacers SPCx, SPCy, and SPCz (i.e., the bottommost end of the bit line spacer SPC) may be at a level lower than the first edge portion EA1 of the active pattern ACT.

Each of the sub-spacers SPCx, SPCy, and SPCz may be formed of or include silicon nitride (SiN), silicon oxide (SiO₂), or silicon oxynitride (SiOC). In an implementation, at least a portion of the sub-spacers SPCx, SPCy, and SPCz may further include an air gap.

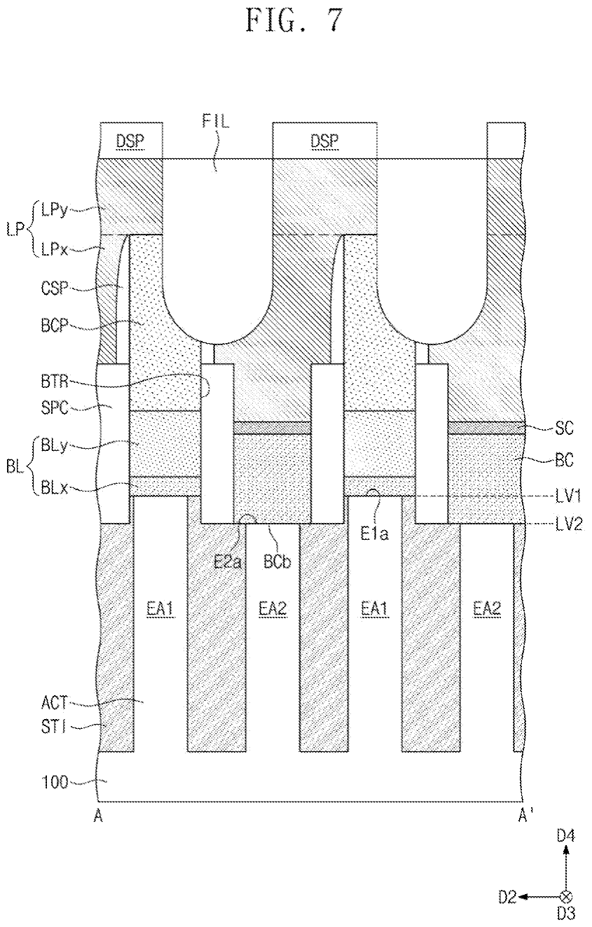

FIG. 7 is a sectional view corresponding to the line A-A′ of FIG. 1A.

Referring to FIG. 7, the bit line spacer SPC may be on a side surface of a lower portion of the bit line capping pattern BCP. A capping spacer CSP may be on the bit line spacer SPC to cover a side surface of an upper portion of the bit line capping pattern BCP. When measured in the second direction D2, a thickness of the capping spacer CSP may be smaller than a thickness of the bit line spacer SPC. Thus, a width of an upper portion of the landing pad LP may be relatively large compared to the case where the bit line spacer SPC is on the side surface of the upper portion of the bit line capping pattern BCP. As a result, the resistance of the landing pad LP may be improved.

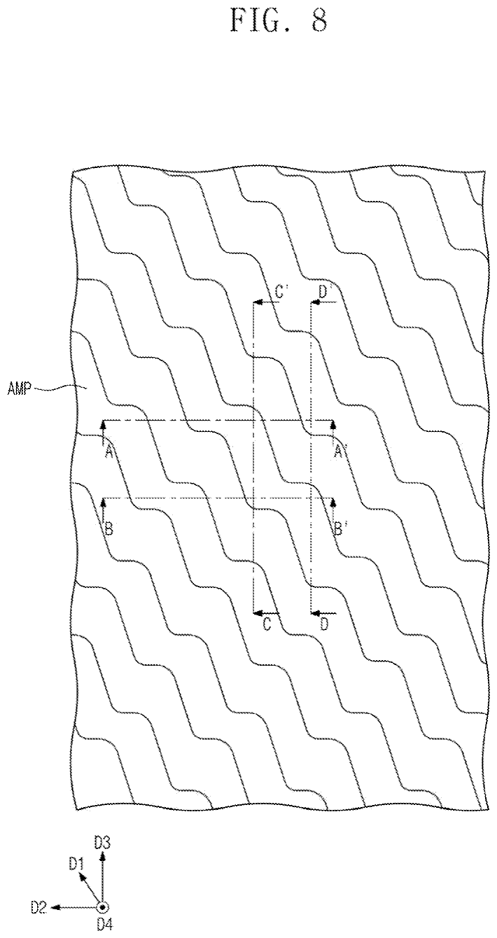

Hereinafter, a fabrication method according to an embodiment will be described in more detail with reference to FIGS. 8 to 25D. In the following description, a previously-described element may be identified by the same reference number without repeating an overlapping description thereof, for concise description.

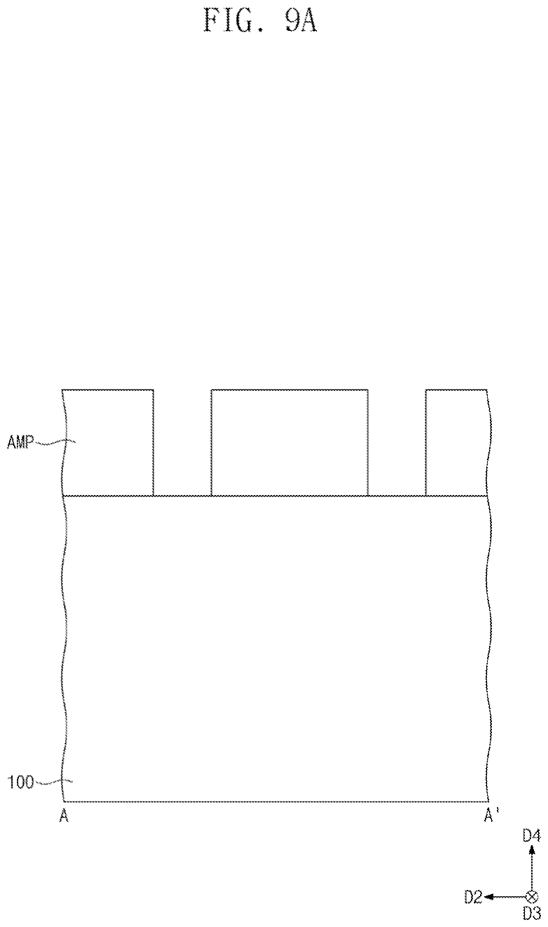

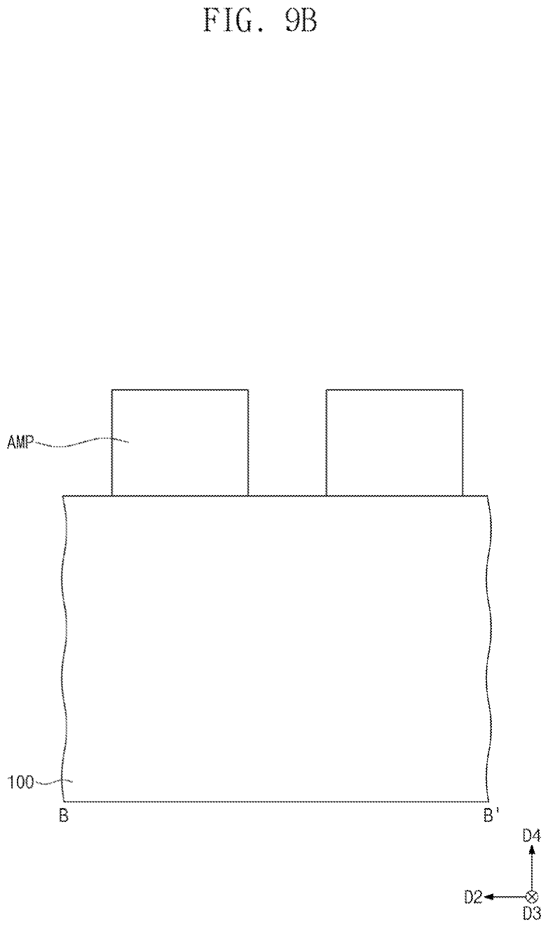

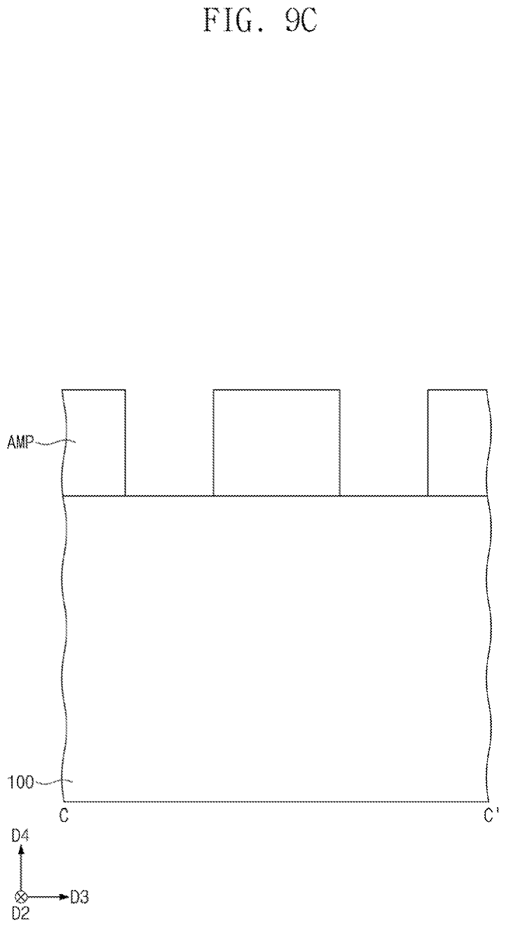

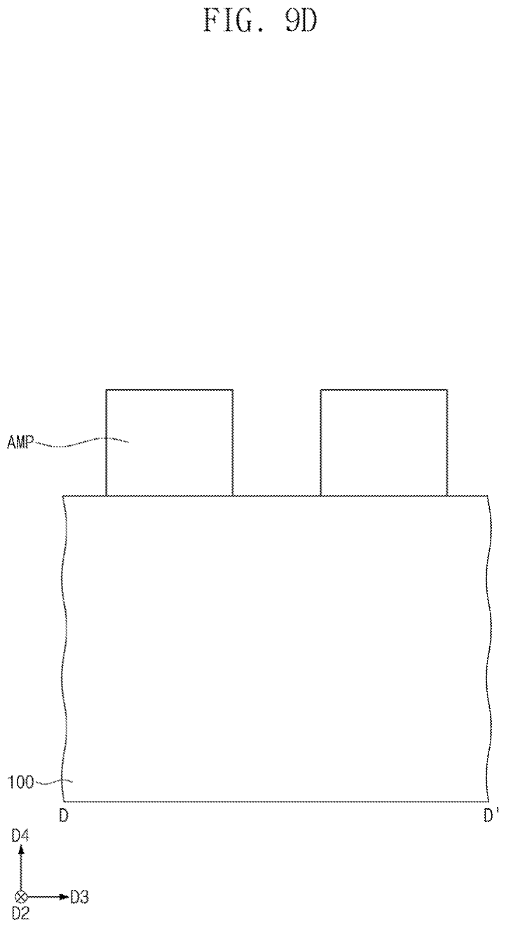

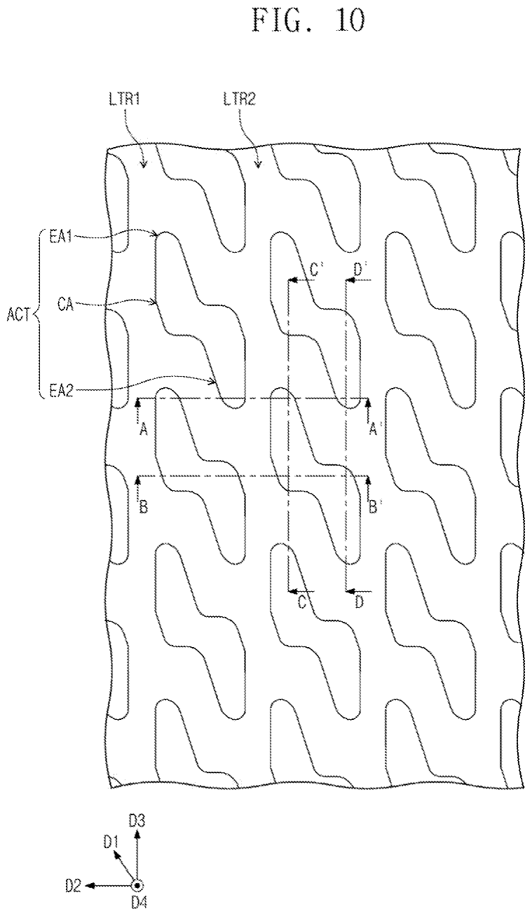

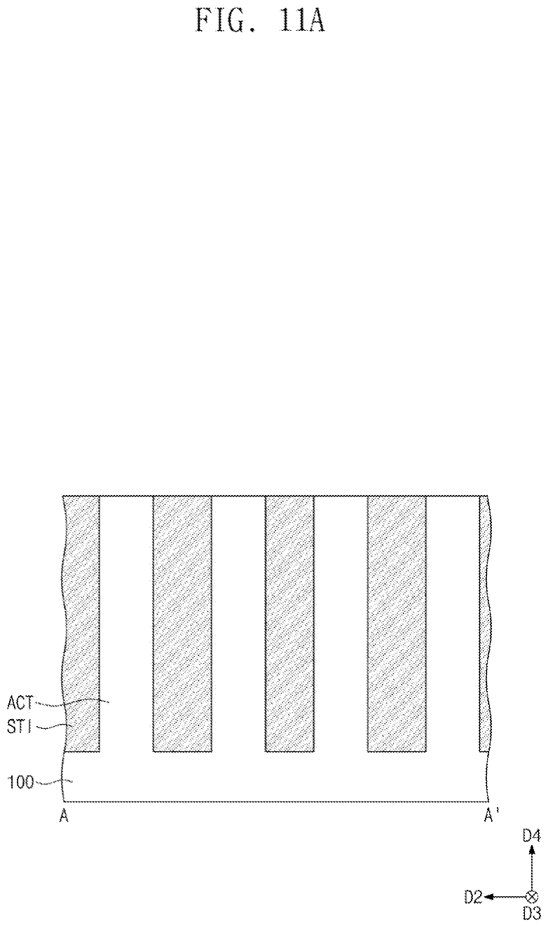

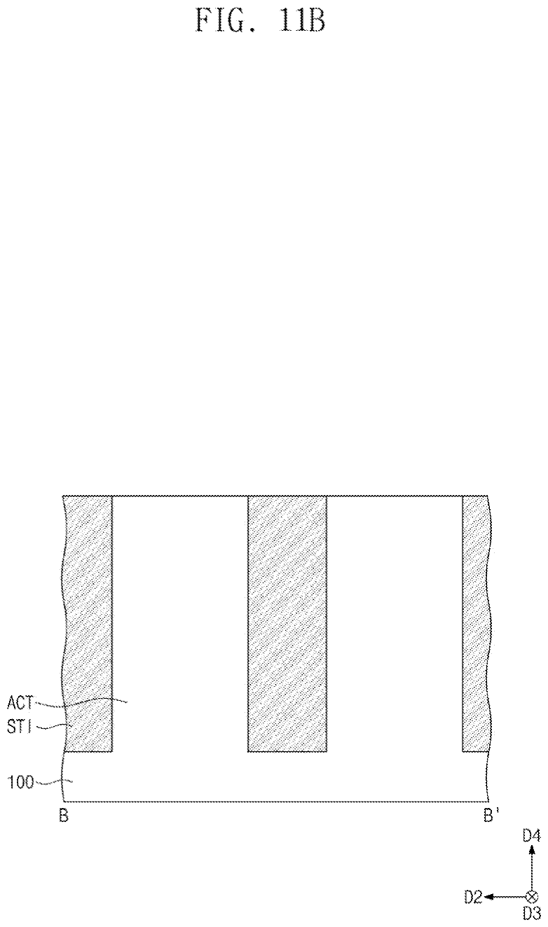

FIGS. 8 to 21D are diagrams of stages in a method of fabricating a semiconductor device, according to an embodiment. In detail, FIGS. 8, 10, 12, 14, 16, 18, and 20 are plan views of stages in a method of fabricating a semiconductor device, according to an embodiment. FIGS. 9A, 11A, 15A, 17A, 19A, and 21A are sectional views corresponding to lines A-A′ of FIGS. 8, 10, 14, 16, 18, and 20. FIGS. 9B, 11B, 13A, 15B, 17B, 19B, and 21B are sectional views corresponding to lines B-B′ of FIGS. 8, 10, 12, 14, 16, 18, and 20. FIGS. 9C, 11C, 13B, 15C, 17C, and 21C are sectional views corresponding to lines C-C′ of FIGS. 8, 10, 12, 14, 16, and 20. FIGS. 9D, 11D, 13C, 15D, 17D, and 21D are sectional views corresponding to lines D-D′ of FIGS. 8, 10, 12, 14, 16, and 20.

Referring to FIGS. 8 to 9D, the substrate 100 may be prepared. A first active mask pattern AMP may be formed on the substrate 100. The first active mask pattern AMP may include a plurality of patterns, which may be elongated in the first direction D1, and trench regions, which may be between the patterns. In an implementation, each of side surfaces of the patterns may have a wiggling or wavy profile, as shown in FIG. 8. In an implementation, each of the side surfaces of the patterns may have a linear profile.

The first active mask pattern AMP may be formed by patterning a patterning process on an active mask layer. In an implementation, the patterning process may include performing an exposure process once. In an implementation, the patterning process may include performing an exposure process at least two times or applying a multi patterning technology.

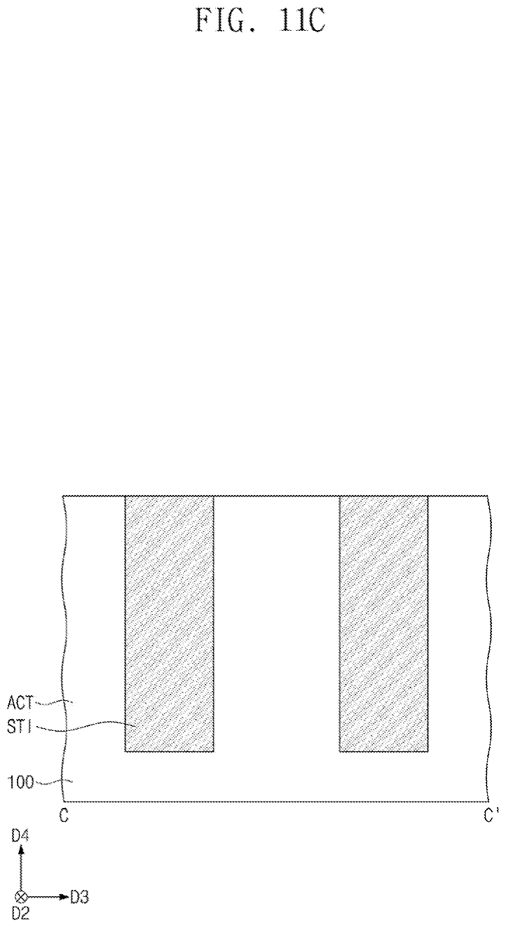

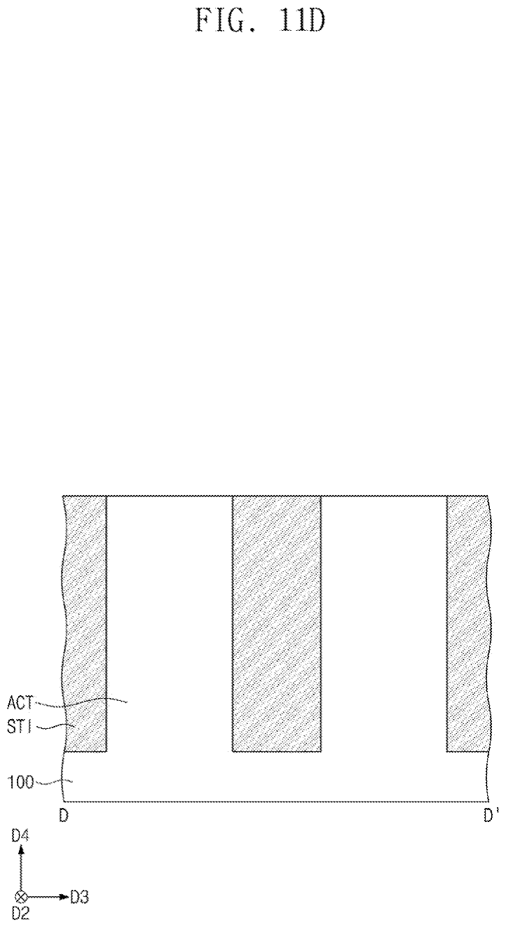

Referring to FIGS. 10 to 11D, a second active mask pattern may be provided on the substrate 100. The second active mask pattern may include a plurality of patterns, which may be elongated in the third direction D3, and trench regions, which may be between the patterns.

A patterning process may be performed on the substrate 100 to form the active patterns ACT. The patterning process may include performing an etching process, in which the first active mask pattern AMP and the second active mask pattern are used as an etch mask, on the substrate 100. As a result of the etching process, a first line trench region LTR1 and a second line trench region LTR2 may be formed between the active patterns ACT. The first line trench region LTR1 may be formed by the trench region of the first active mask pattern AMP. The first line trench region LTR1 between the active patterns ACT may extend in the first direction D1. The second line trench region LTR2 may be formed by the trench region of the second active mask pattern. The second line trench region LTR2 between the active patterns ACT may extend in the third direction D3.

The profile of the active pattern ACT may be variously changed, depending on the profile and disposition of the first active mask pattern AMP and the second active mask pattern. In an implementation, the active pattern ACT may be formed to have the profile of FIGS. 3A to 3E, depending on the profile and disposition of the first active mask pattern AMP and the second active mask pattern.

The device isolation pattern STI may be formed to fill the first and second line trench regions LTR1 and LTR2. The formation of the device isolation pattern STI may further include performing a physical vapor deposition (PVD) process, a chemical vapor deposition (CVD) process, or an atomic layer deposition (ALD) process.

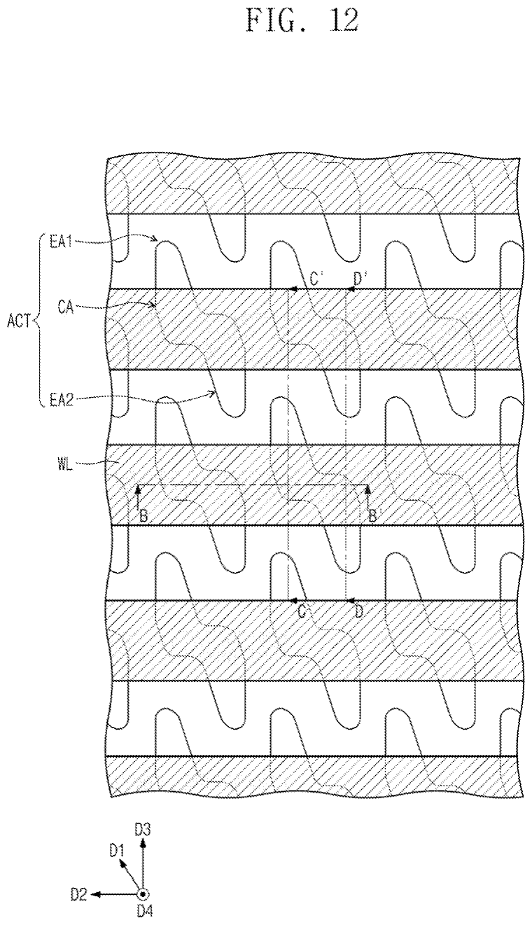

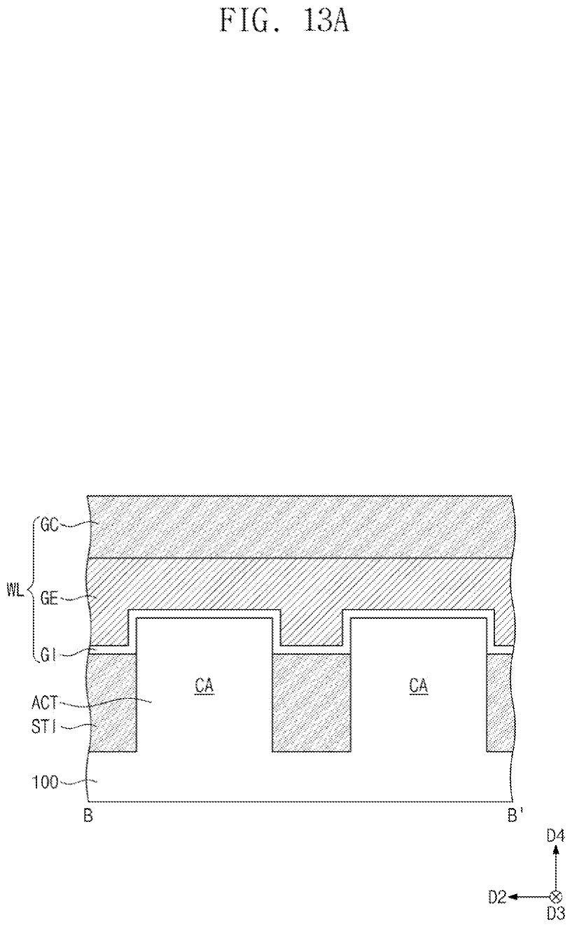

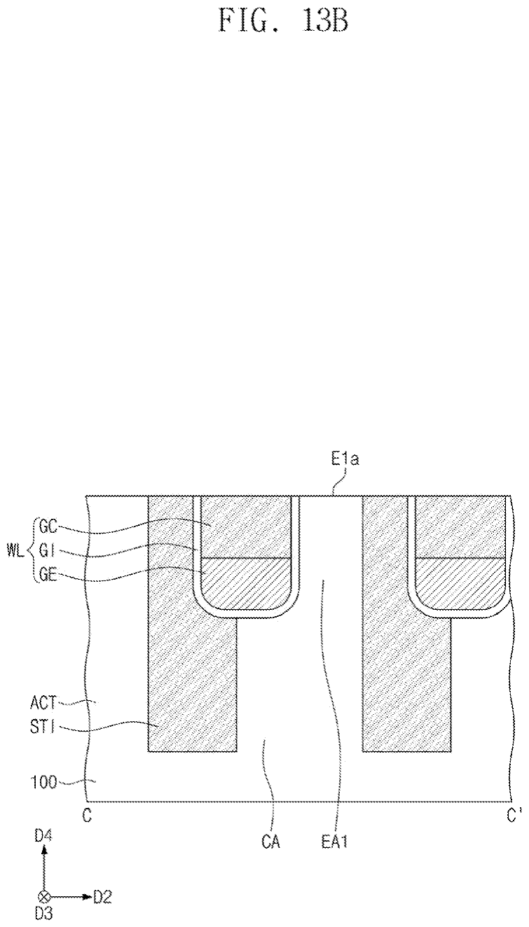

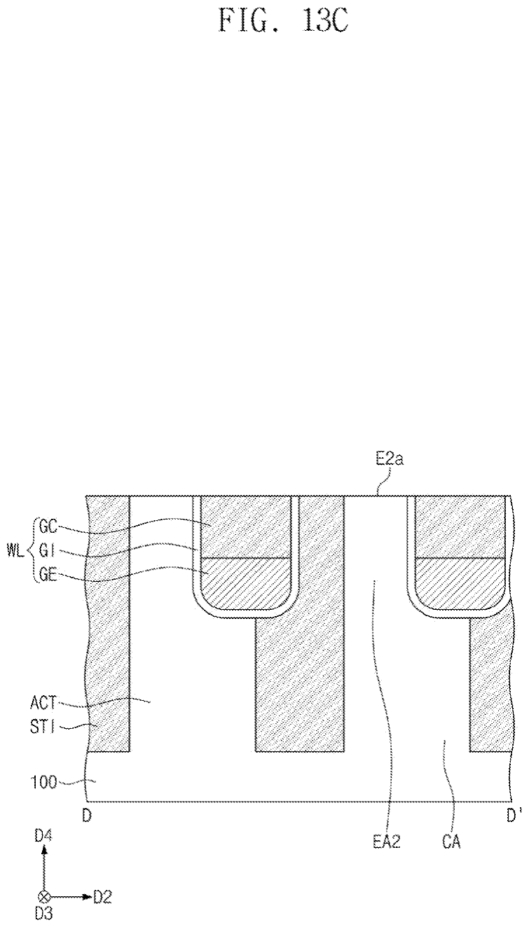

Referring to FIGS. 12 to 13C, the word line WL may be formed to cross the active pattern ACT and the device isolation pattern STI. The formation of the word line WL may include forming a mask pattern on the active pattern ACT and the device isolation pattern STI, performing an anisotropic etching process using the mask pattern to form a trench region crossing the active pattern ACT and the device isolation pattern STI, and filling the trench region with the word line WL. The word line WL may be formed on the center portion CA of the active pattern ACT and between the first and second edge portions EA1 and EA2.

In an implementation, the filling of the word line WL may include conformally depositing the gate dielectric pattern GI on an inner surface of the trench region, filling the trench region with a conductive layer, performing an etch-back and/or polishing process on the conductive layer to form the gate electrode GE, and forming the gate capping pattern GC on the gate electrode GE to fill a remaining portion of the trench region.

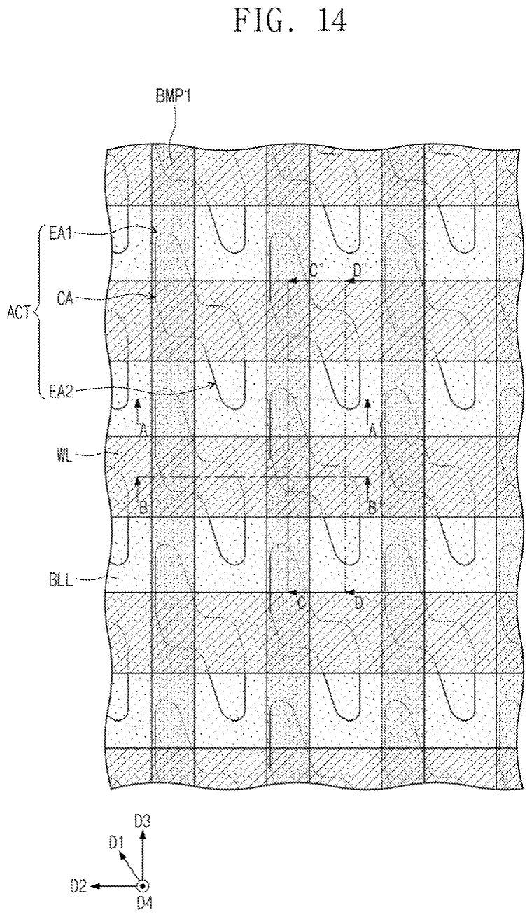

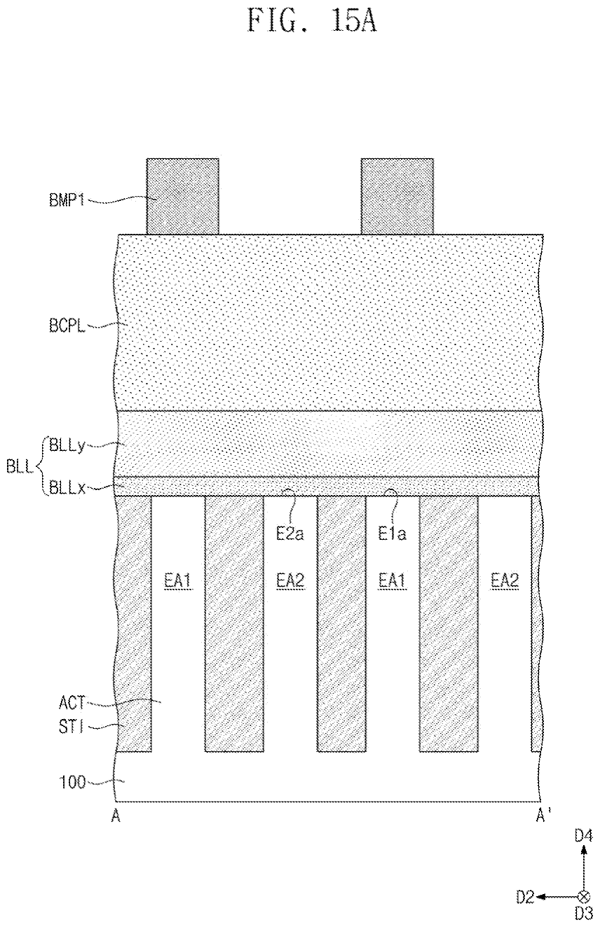

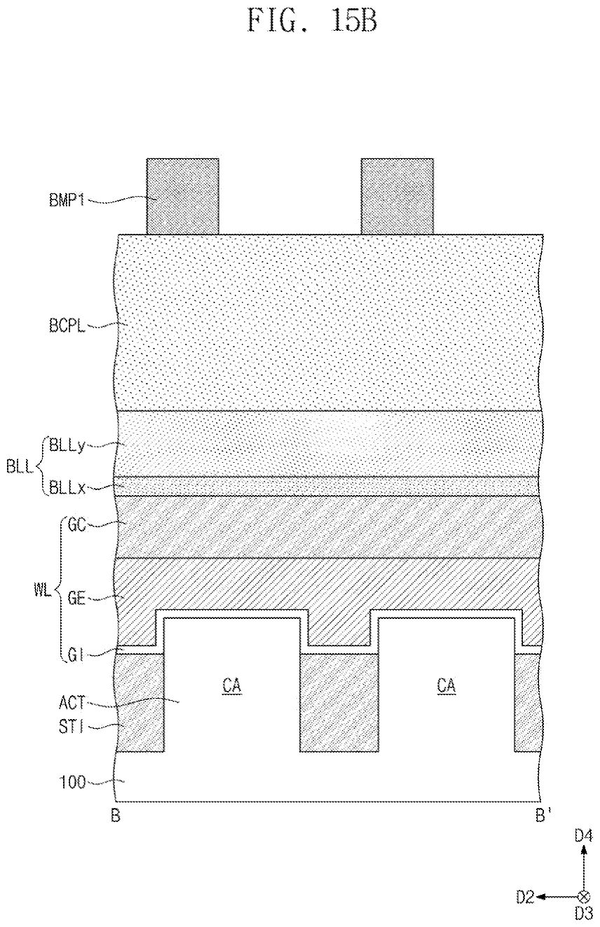

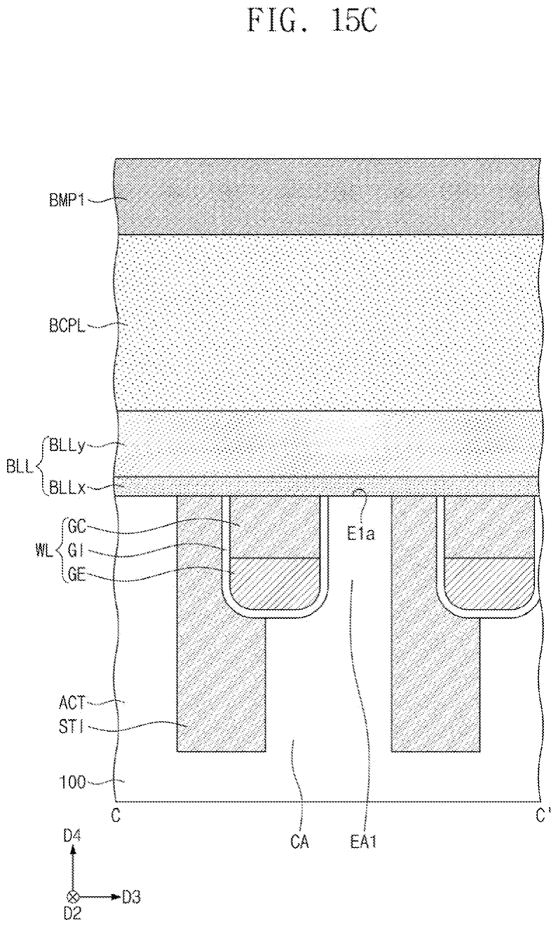

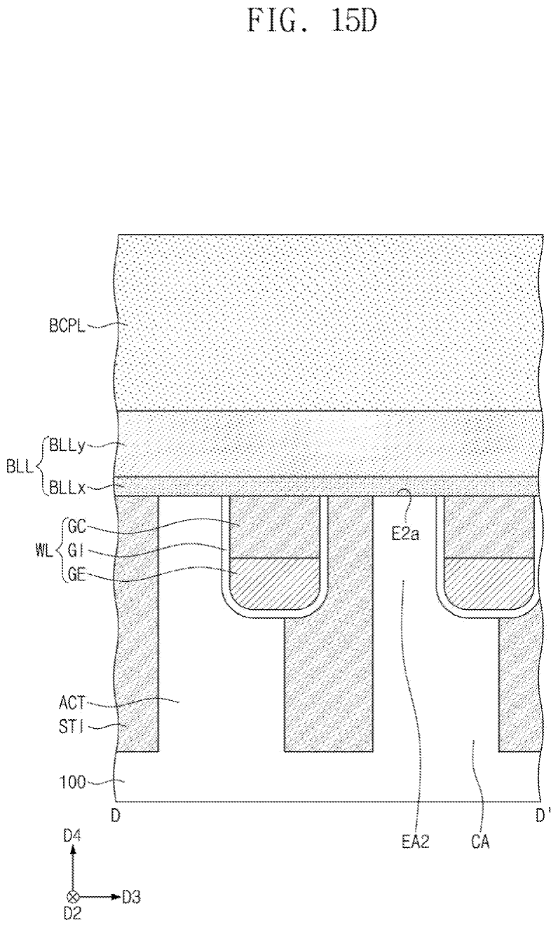

Referring to FIGS. 14 to 15D, a bit line layer BLL and a bit line capping layer BCPL may be formed on the substrate 100. In an implementation, the bit line layer BLL may be formed to be in contact with the first and second edge portions EA1 and EA2 of the active pattern ACT. The bit line layer BLL may include a lower bit line layer BLLx and an upper bit line layer BLLy. In an implementation, the lower bit line layer BLLx may be formed on the entire top surface of the substrate 100, and in this case, the semiconductor device may be fabricated have substantially the same final structure as that in the embodiment of FIGS. 2A to 2D. In an implementation, the lower bit line layer BLLx may be selectively formed on the first and second edge portions EA1 and EA2, and in this case, the semiconductor device may be fabricated have substantially the same final structure as that in the embodiment of FIGS. 5A and 5B.

A first bit line mask pattern BMP1 may be formed on the bit line capping layer BCPL. The first bit line mask pattern BMP1 may include a plurality of mask patterns, which may be spaced apart from each other in the second direction D2 and extend in the third direction D3. The first bit line mask pattern BMP1 may be formed on the first edge portion EA1 of the active pattern ACT. The first bit line mask pattern BMP1 may fully cover the top surface Ela of the first edge portion EA1. The first bit line mask pattern BMP1 may be offset from the second edge portion EA2 of the active pattern ACT in the second direction D2. The first bit line mask pattern BMP1 may not be vertically overlapped with the second edge portion EA2.

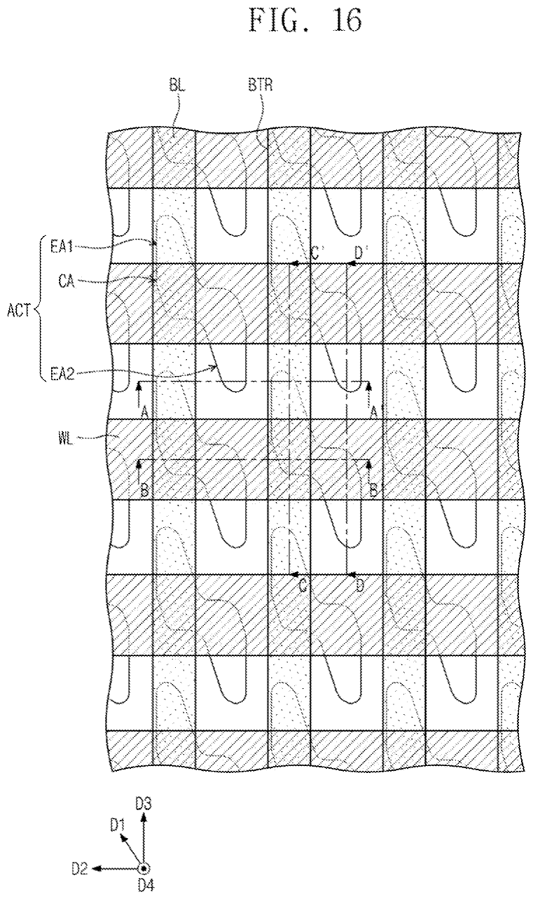

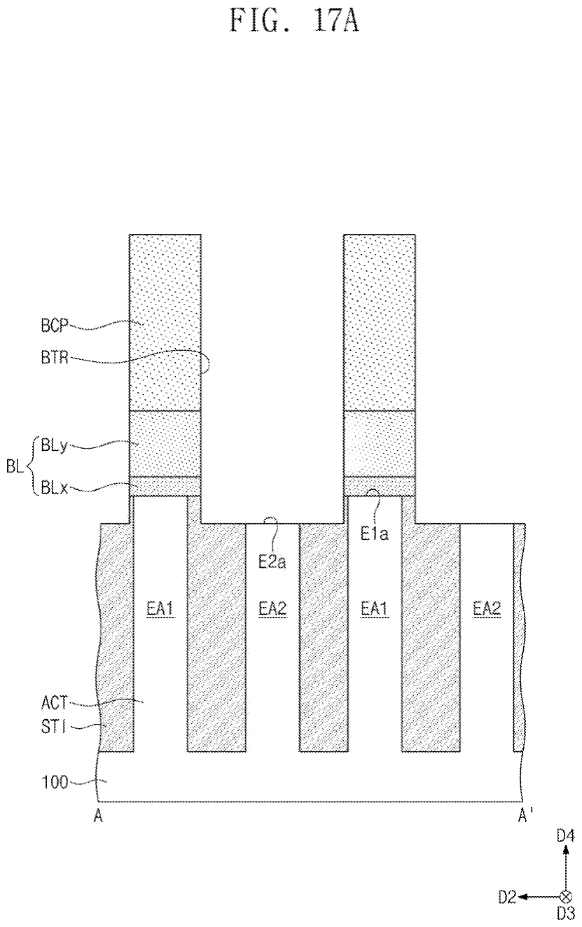

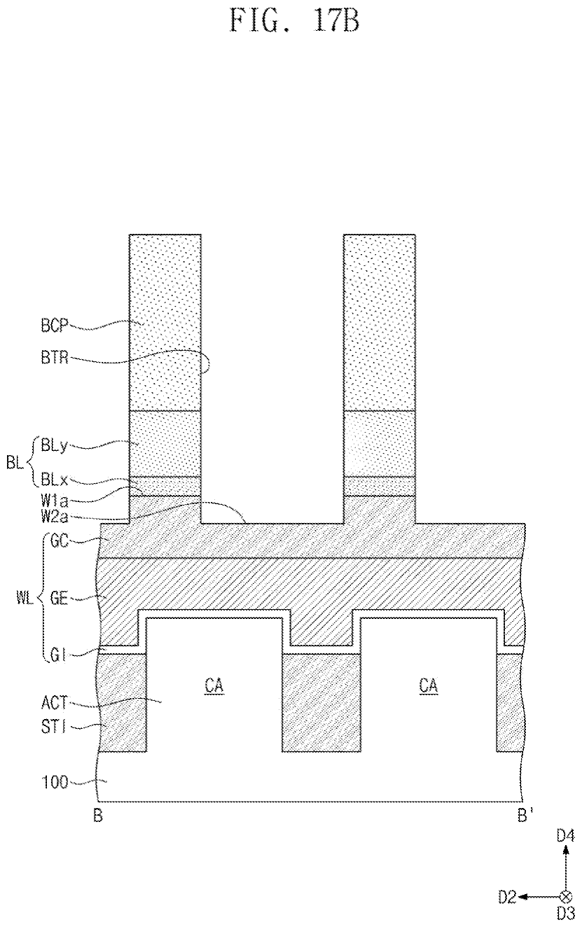

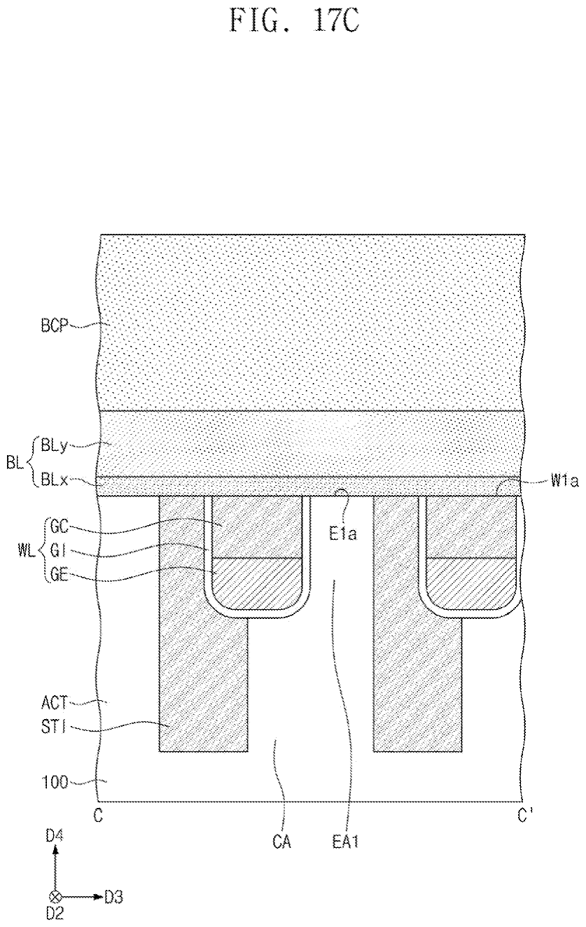

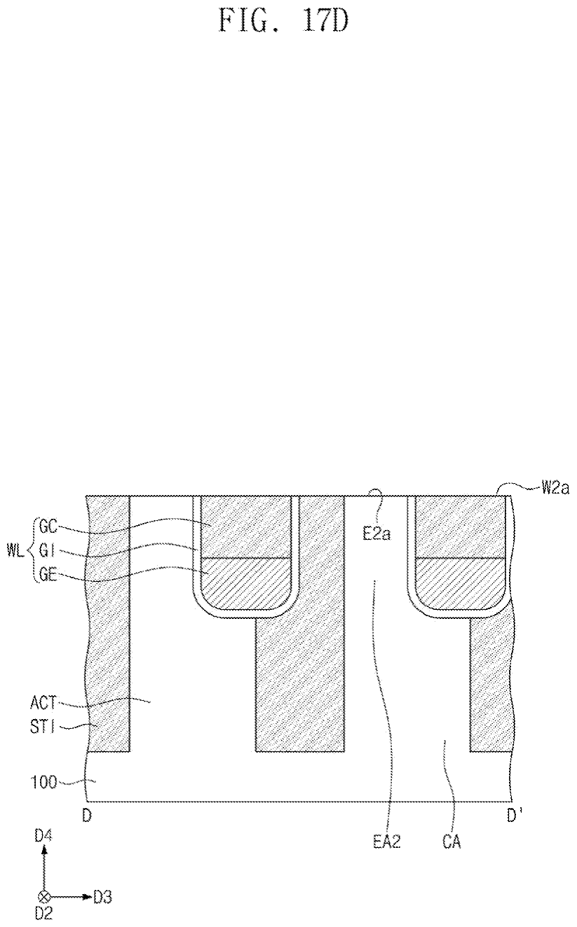

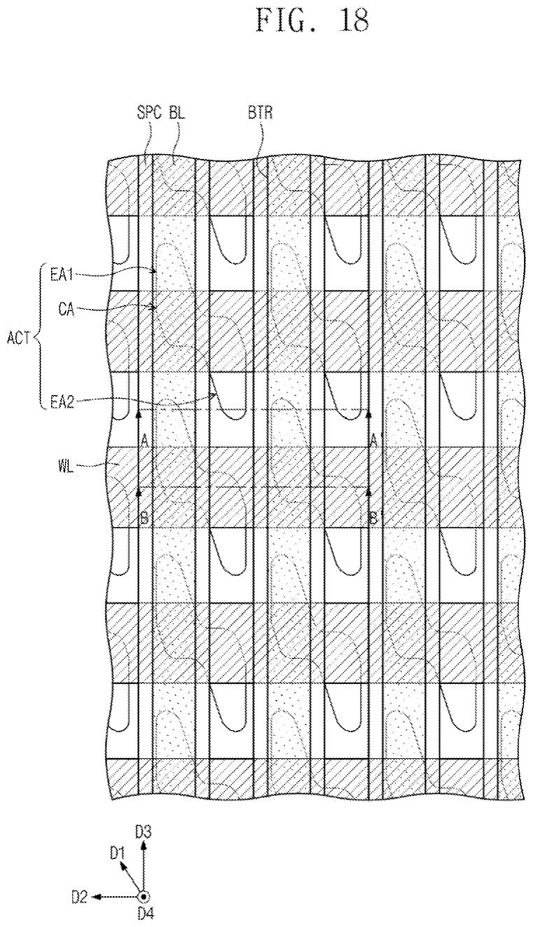

Referring to FIGS. 16 to 17D, the bit line capping pattern BCP and the bit line BL may be formed by performing an etching process, in which the first bit line mask pattern BMP1 is used as an etch mask, on the bit line capping layer BCPL and the bit line layer BLL. In an implementation, the bit line trench region BTR may be formed between the bit line capping patterns BCP, which are adjacent to each other in the second direction D2, and between the bit lines BL, which are adjacent to each other in the second direction D2. The top surface E2a of the second edge portion EA2 may be exposed to the outside through the inner bottom surface of the bit line trench region BTR. In an implementation, the entire region of the top surface E2a of the second edge portion EA2 may be exposed to the outside through the inner bottom surface of the bit line trench region BTR. In an implementation, the top surface Ela of the first edge portion EA1 may not be exposed to the outside, after the etching process.

The etching process may be performed such that the top surface E2a of the second edge portion EA2, which is offset from the first bit line mask pattern BMP1, is recessed, compared with the top surface Ela of the first edge portion EA1 covered with the first bit line mask pattern BMP1. In an implementation, the top surface E2a of the second edge portion EA2 may be recessed, and a distance from the second edge portion EA2 to the bit line BL may be increased. Thus, an interference phenomenon between the second edge portion EA2 and the bit line BL may be prevented, and as a result, the electrical and reliability characteristics of the semiconductor device may be improved.

In an implementation, as a result of the etching process, the inner bottom surface of the bit line trench region BTR may be formed at a level lower than the top surface Ela of the first edge portion EA1. A portion of a top surface of the word line WL may also be recessed to define the first and second top surfaces W1a and W2a that are distinct from each other.

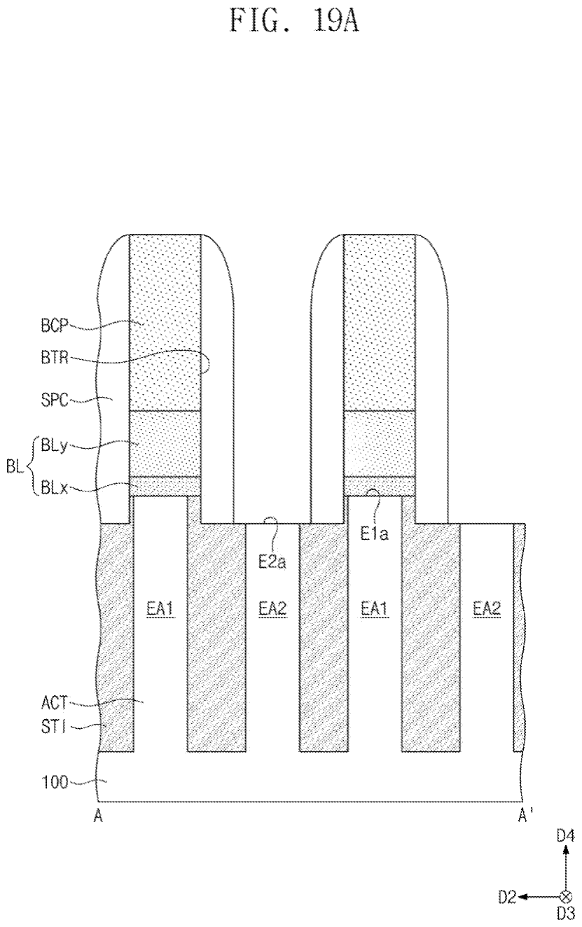

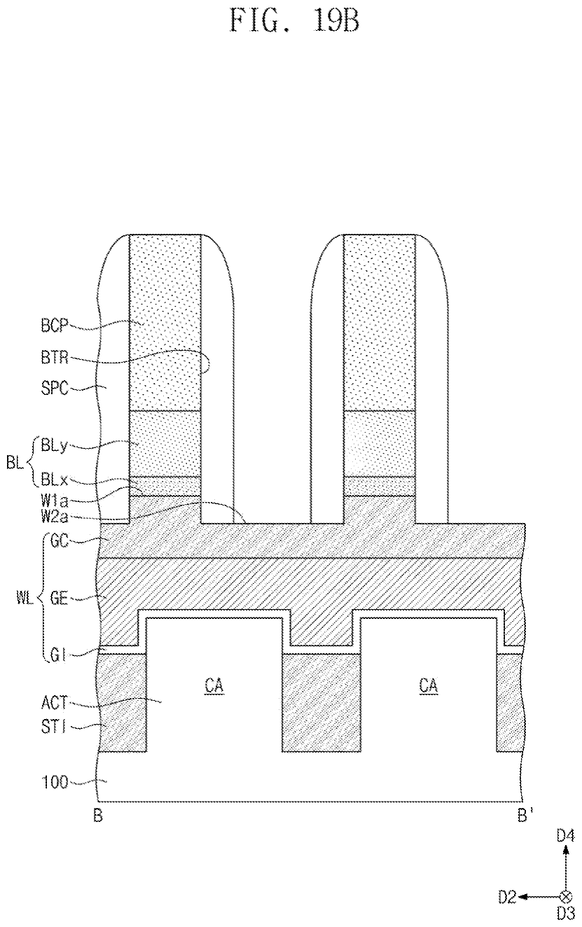

Referring to FIGS. 18 to 19B, the bit line spacer SPC may be formed on the side surface of the bit line BL. The formation of the bit line spacer SPC may include forming a bit line spacer layer to cover an inner surface of the bit line trench region BTR and removing the bit line spacer layer from the top surface E2a of the second edge portion EA2 to form the bit line spacer SPC. In an implementation, the bit line spacer SPC may include a plurality of sub-spacers, and the formation of the bit line spacer SPC may include performing a step of forming and patterning a sub-spacer layer several times. As a result, the semiconductor device may be fabricated to have substantially the same structure as that of FIGS. 6A and 6B. After the formation of the bit line spacer SPC, the top surface E2a of the second edge portion EA2 may be exposed to the outside. The bit line spacer SPC may be formed to cover an inner side surface of the bit line trench region BTR.

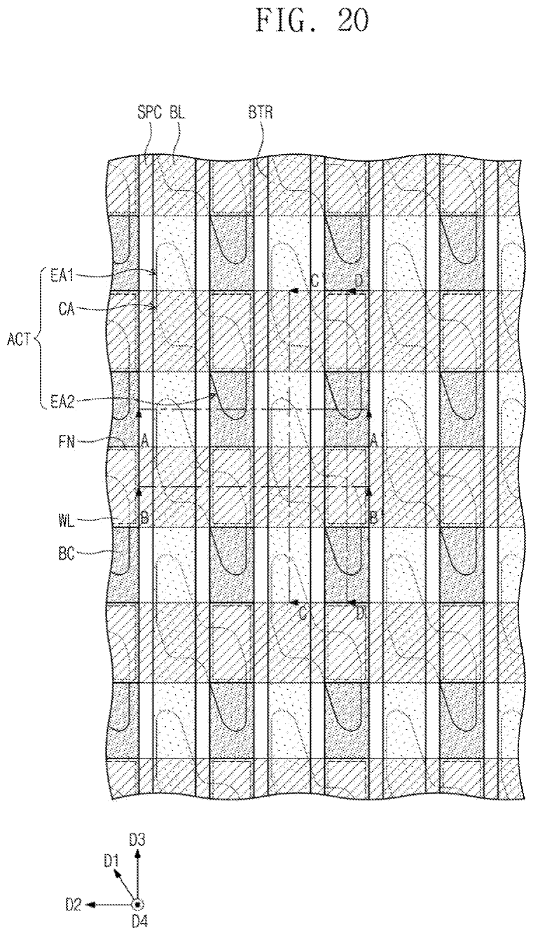

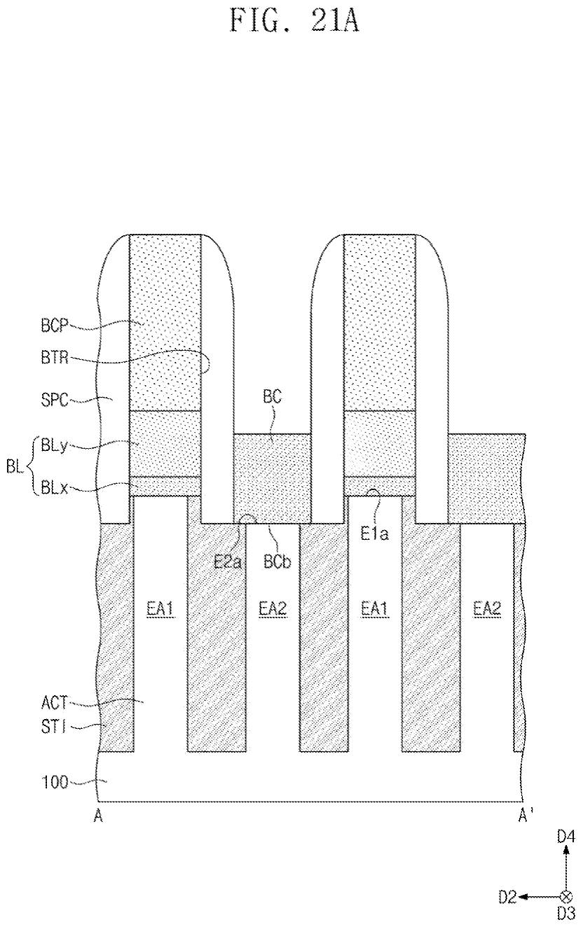

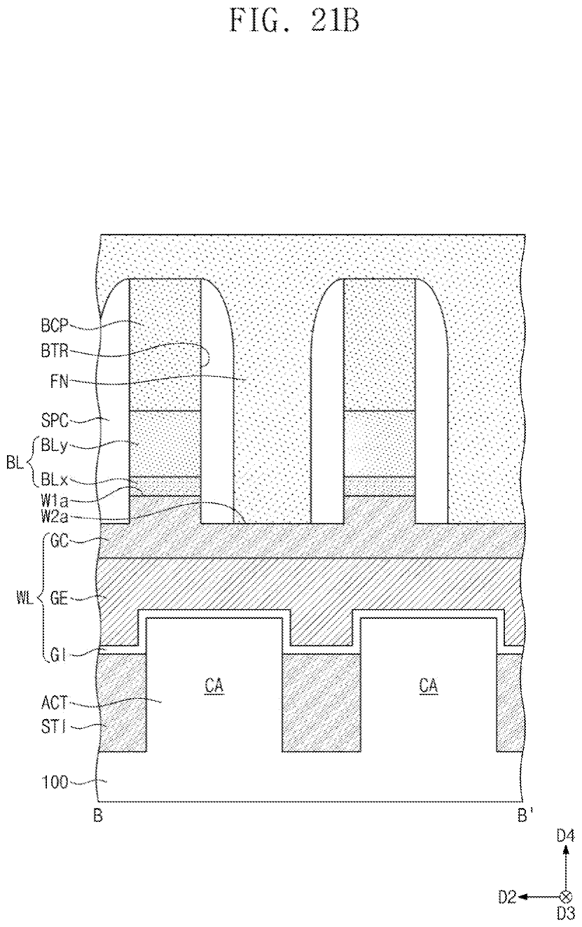

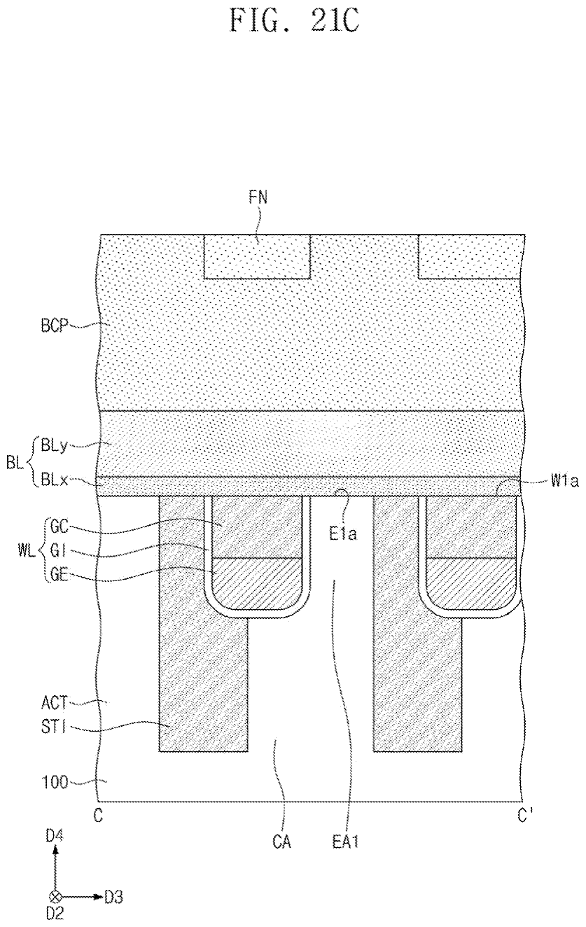

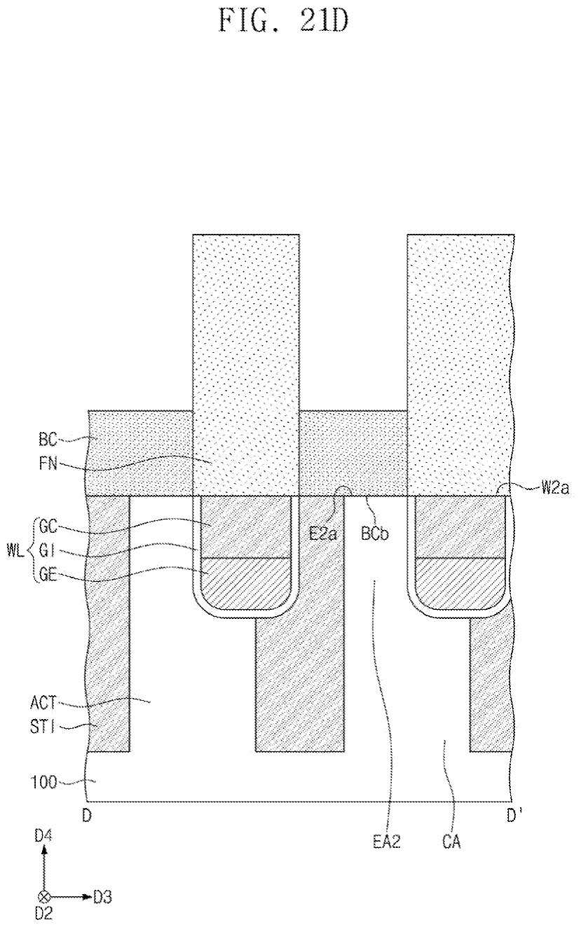

Referring to FIGS. 20 to 21D, the storage node contacts BC and the fence patterns FN may be formed between adjacent ones of the bit lines BL. The storage node contacts BC and the fence patterns FN may be alternatively arranged in the third direction D3. The storage node contact BC may be formed on the second edge portion EA2 of the active pattern ACT.

In an implementation, the formation of the storage node contacts BC and the fence patterns FN may include forming a storage node contact line to fill the bit line trench region BTR and forming the fence patterns FN to divide the storage node contact line into the storage node contacts BC. The fence patterns FN, which may be adjacent to each other in the second direction D2, may be connected to each other on the bit line capping pattern BCP.

Thereafter, an upper portion of the storage node contact BC may be removed. In an implementation, the removal process may include performing an etch-back process on the storage node contact BC. As a result, a top surface of the storage node contact BC may be recessed.

In an implementation, the etch-back process may include a first etch-back process and a second etch-back process, and in this case, the semiconductor device may be fabricated to have the structure of FIG. 7. In an implementation, the first etch-back process may be performed to remove a first upper portion of the storage node contact BC, and an upper portion of the bit line spacer SPC may also be removed during this process. Before the second etch-back process, a capping spacer layer may be formed on the entire surface of the substrate 100. Thereafter, the capping spacer layer on the storage node contact BC as well as a second upper portion of the storage node contact BC may be removed through the second etch-back process. An unremoved or remaining portion of the capping spacer layer may constitute the capping spacer CSP of FIG. 7. In another embodiment, as shown in FIG. 21A, the etch-back process may be composed of an etch-back step that is performed once.

Referring back to FIGS. 1A to 2D, the landing pads LP may be formed on the storage node contacts BC. The formation of the landing pads LP may include sequentially forming a landing pad layer and mask patterns to cover top surfaces of the storage node contacts BC and performing an anisotropic etching process using the mask patterns as an etch mask to divide the landing pad layer into a plurality of landing pads LP. In an implementation, the second silicide pattern SC and the second barrier pattern may be additionally formed, before the formation of the landing pads LP.

Next, the filling pattern FIL may be formed in a region, which may be formed by removing the landing pad layer. The filling pattern FIL may be formed to enclose each of the landing pads LP. The data storage pattern DSP may be formed on each of the landing pads LP.

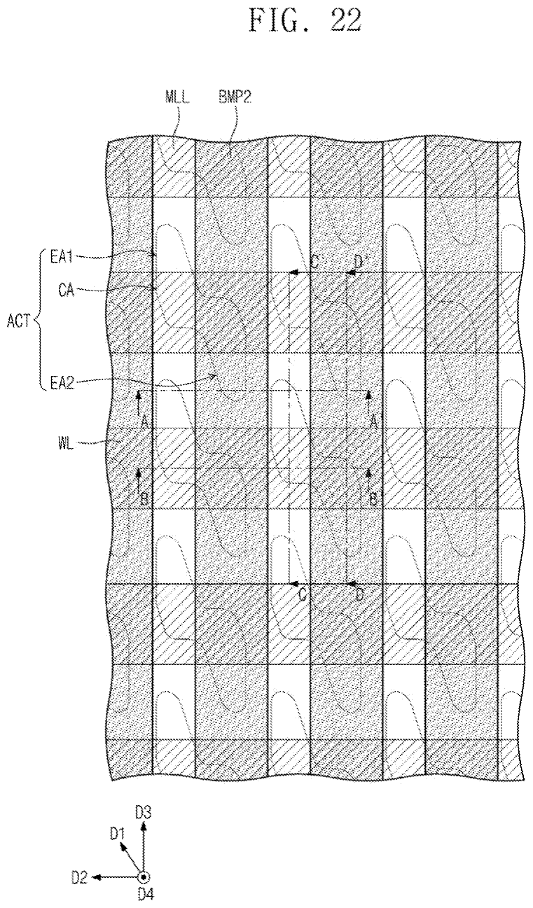

FIGS. 22 to 25D are diagrams of stages in a method of fabricating a semiconductor device, according to an embodiment.

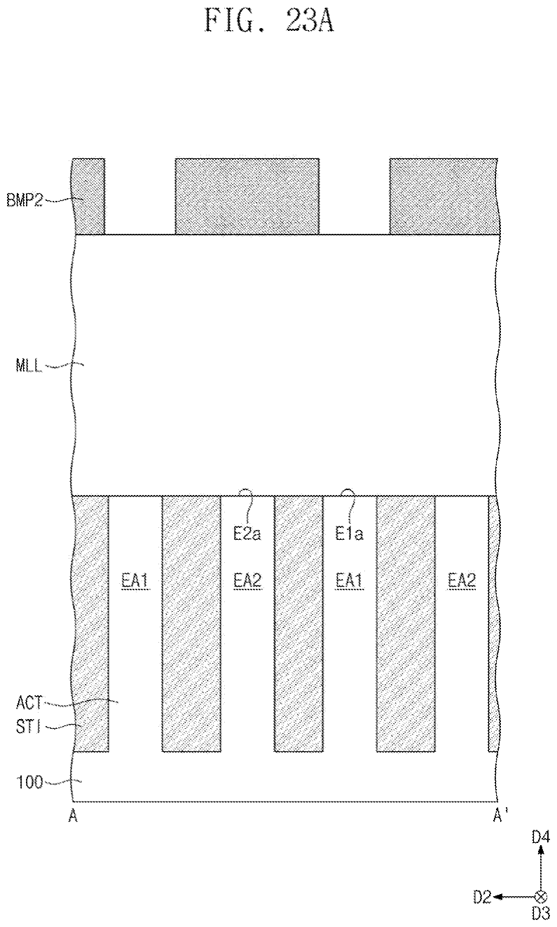

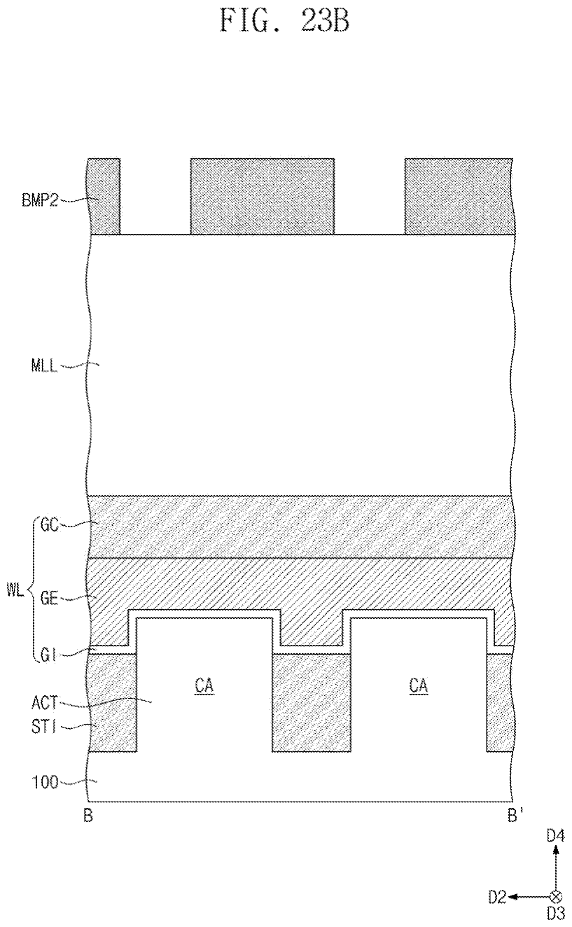

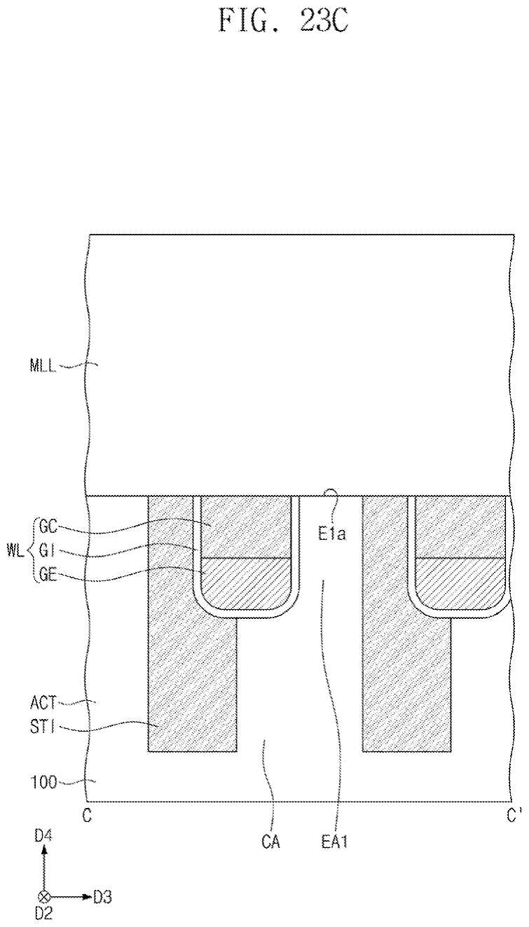

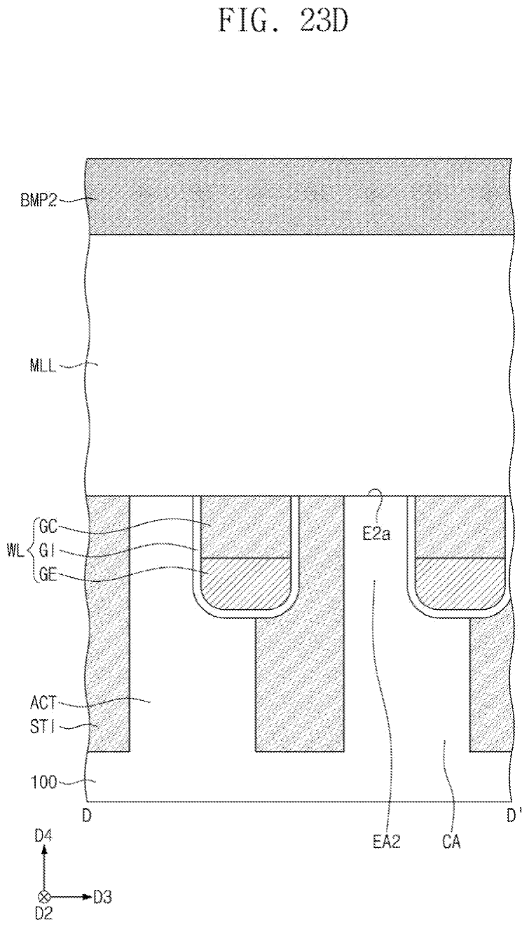

Referring to FIGS. 22 to 23D, a mold layer MLL may be formed on the entire top surface of the substrate 100, after the formation of the word line WL described with reference to FIGS. 12 to 13D. The mold layer MLL may fully cover the first and second edge portions EA1 and EA2 of the active pattern ACT.

A second bit line mask pattern BMP2 may be formed on the mold layer MLL. The second bit line mask pattern BMP2 may include a plurality of mask patterns, which are spaced apart from each other in the second direction D2 and are extended in the third direction D3. The second bit line mask pattern BMP2 may be formed on the second edge portion EA2 of the active pattern ACT. In an implementation, the second bit line mask pattern BMP2 may fully cover the top surface E2a of the second edge portion EA2. The second bit line mask pattern BMP2 may be offset from the first edge portion EA1 of the active pattern ACT in the second direction D2. The second bit line mask pattern BMP2 may not be vertically overlapped with the first edge portion EA1.

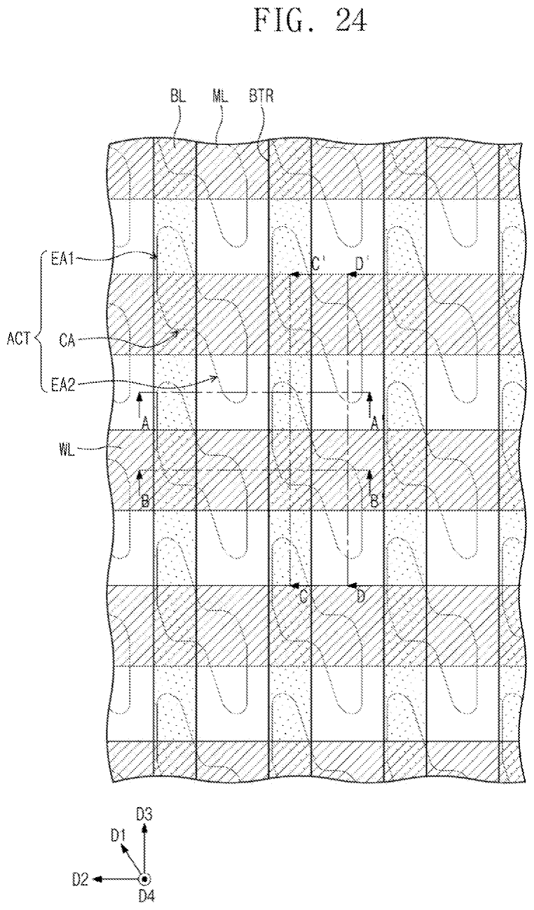

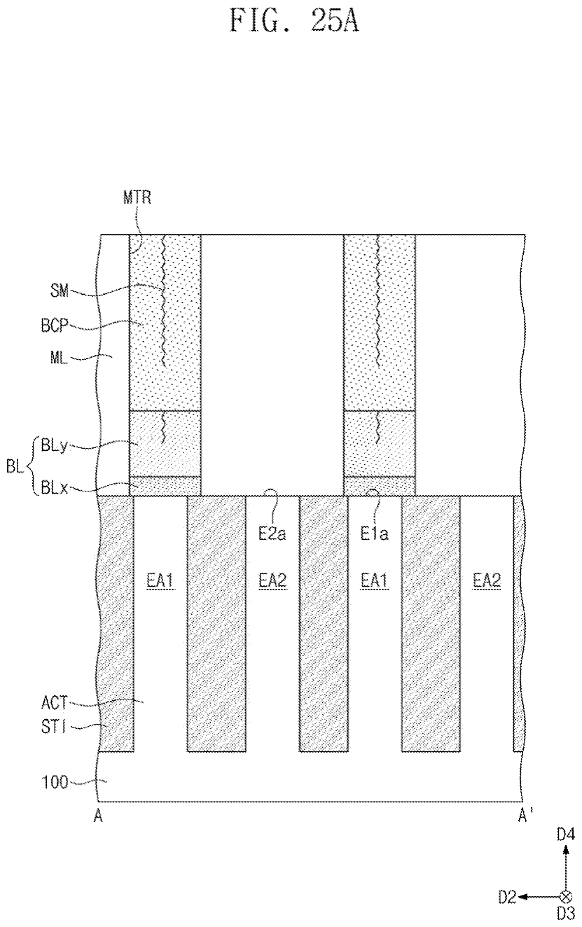

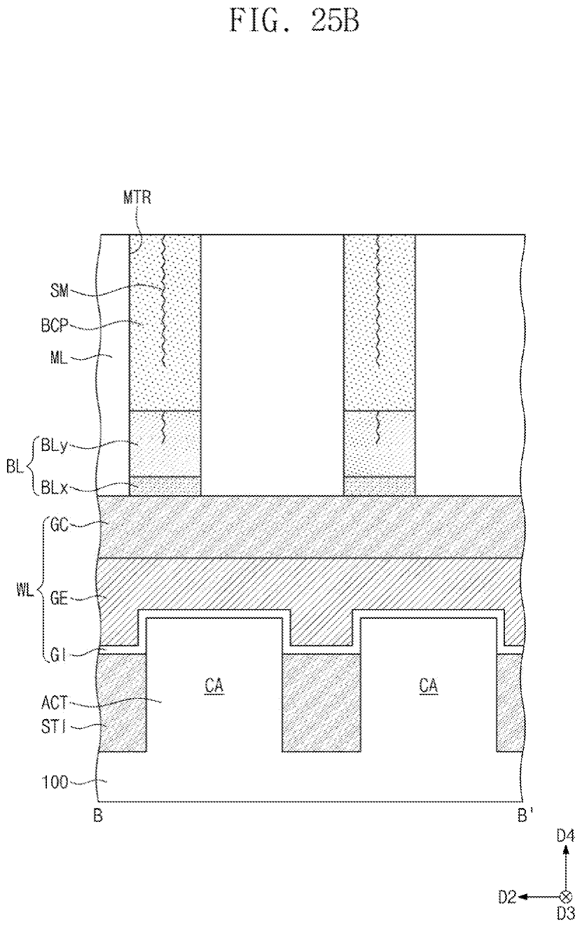

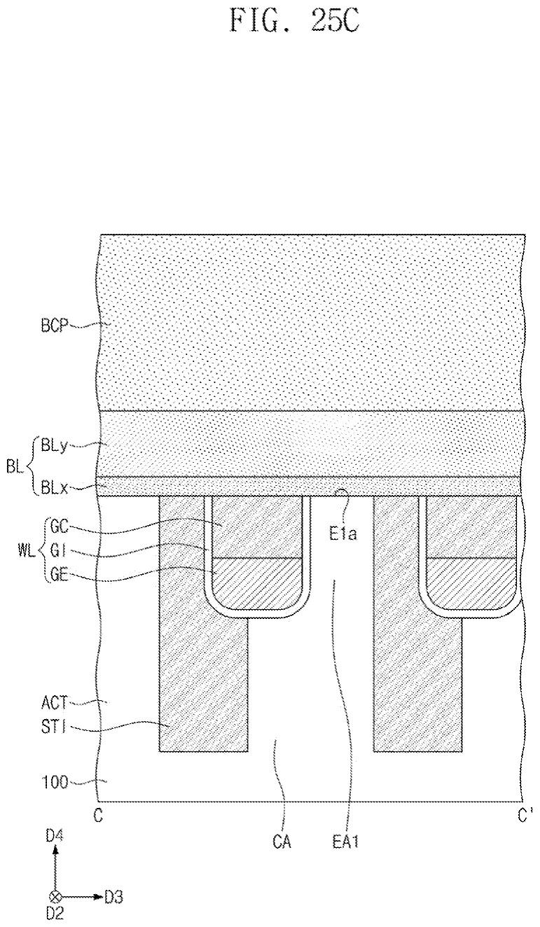

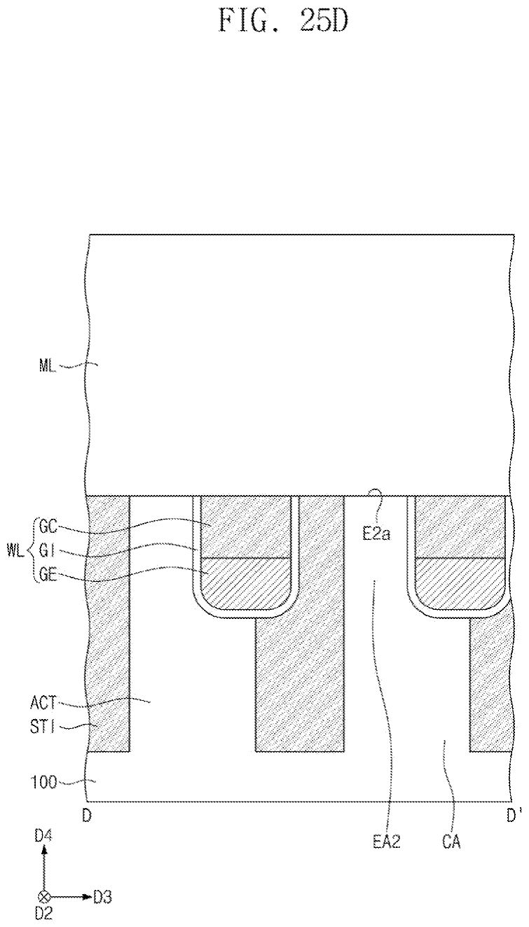

Referring to FIGS. 24 to 25D, an etching process, in which the second bit line mask pattern BMP2 is used as an etch mask, may be performed on the mold layer MLL, and as a result, a mold pattern ML may be formed in a region that is vertically overlapped with the second bit line mask pattern BMP2. A mold trench region MTR may also be formed between the mold patterns ML, which may be adjacent to each other in the second direction D2. The top surface Ela of the first edge portion EA1 may be exposed to the outside through an inner bottom surface of the mold trench region MTR. The entire region of the top surface Ela of the first edge portion EA1 may be exposed to the outside through the inner bottom surface of the mold trench region MTR. In an implementation, the top surface E2a of the second edge portion EA2 may be covered with the mold pattern ML and may not be exposed through the mold trench region MTR.

Thereafter, the bit line BL and the bit line capping pattern BCP may be formed in the mold trench region MTR. Each of the bit line BL and the bit line capping pattern BCP may be formed by a physical vapor deposition (PVD) process, a chemical vapor deposition (CVD) process, or an atomic layer deposition (ALD) process. In an implementation, at least one of the bit line BL and the bit line capping pattern BCP may be formed to include the seam SM therein. In the case where a layer for the bit line BL or the bit line capping pattern BCP is deposited on the opposite inner side surfaces of the mold trench region MTR, the layer may be grown to form an unfilled space or a discontinuous interface (e.g., the seam SM). As a result of the afore-described fabrication process, the semiconductor device may be fabricated to have the structure of FIGS. 4A and 4B. However, even when the fabrication process is performed by the method described with reference to FIGS. 22 to 25D, the seam SM may not be formed by adjusting the process condition or performing an additional process.

By way of summation and review, due to the recent increasing demand for electronic devices with a fast speed and/or low power consumption, the semiconductor device may have a fast operating speed and/or a low operating voltage. Accordingly, an integration density of the semiconductor device may be increased. Thus, realizing a highly-integrated semiconductor device may be considered.

According to an embodiment, elements in a semiconductor device may be disposed in a simplified manner. Accordingly, it may be possible to reduce a process difficulty in a patterning process, which is performed to fabricate a semiconductor device, and consequently to easily fabricate the semiconductor device. In addition, the elements may be disposed in a relatively simple manner, and an integration density of the semiconductor device may also be increased.

Furthermore, a top surface of a second edge portion may be located at a level that is lower than a top surface of a first edge portion of an active pattern. Thus, a distance from the second edge portion to a bit line may be relatively increased to help prevent an interference phenomenon between the second edge portion and the bit line. As a result, the electrical and reliability characteristics of the semiconductor device may be improved.

One or more embodiments may provide a method of easily fabricating a highly-integrated semiconductor device.

One or more embodiments may provide a semiconductor device with improved electrical and reliability characteristics.

Example embodiments have been disclosed herein, and although specific terms are employed, they are used and are to be interpreted in a generic and descriptive sense only and not for the purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A semiconductor device, comprising:
a first active pattern including a first edge portion and a second edge portion, which are spaced apart from each other in a first direction;
a first word line between the first edge portion of the first active pattern and the second edge portion of the first active pattern and extending in a second direction that crosses the first direction;
a bit line on the first edge portion of the first active pattern and extending in a third direction that crosses the first direction and the second direction; and
a storage node contact on the second edge portion of the first active pattern,
wherein a top surface of the first edge portion is at a level higher than a top surface of the second edge portion.

2. The semiconductor device as claimed in claim 1, wherein the top surface of the first edge portion is at a level higher than a bottom end of the storage node contact.

3. The semiconductor device as claimed in claim 1, wherein:
a portion of a top surface of the first word line is below the bit line, and
the portion of the top surface of the first word line is at substantially the same level as the top surface of the first edge portion.

4. The semiconductor device as claimed in claim 1, wherein the bit line is offset from the second edge portion in the second direction, at a level higher than the second edge portion of the first active pattern.

5. The semiconductor device as claimed in claim 1, wherein the bit line fully covers the top surface of the first edge portion.

6. The semiconductor device as claimed in claim 1, wherein the storage node contact fully covers the top surface of the second edge portion.

7. The semiconductor device as claimed in claim 1, further comprising a bit line spacer on a side surface of the bit line,
wherein the storage node contact is spaced apart from the first edge portion with the bit line spacer therebetween.

8. The semiconductor device as claimed in claim 1, further comprising a bit line spacer on a side surface of the bit line,
wherein a bottommost end of the bit line spacer is at a level lower than the top surface of the first edge portion.

9. The semiconductor device as claimed in claim 1, wherein the bit line is in contact with the first edge portion of the first active pattern.

10. The semiconductor device as claimed in claim 1, further comprising:
a second active pattern, which is adjacent to the first active pattern in the second direction;
a third active pattern, which is adjacent to the second active pattern in the third direction; and
a fourth active pattern, which is adjacent to the first active pattern in the third direction,
wherein a second edge portion of the fourth active pattern, the first edge portion of the first active pattern, a second edge portion of the third active pattern, and a first edge portion of the second active pattern are disposed, in the order enumerated, in the second direction.

11. The semiconductor device as claimed in claim 10, further comprising a second word line, which is adjacent to the first word line in the third direction,
wherein:
the first word line crosses the first active pattern and the second active pattern, and
the second word line crosses the third active pattern and the fourth active pattern.

12. The semiconductor device as claimed in claim 1, further comprising a bit line capping pattern on the bit line,
wherein the bit line or the bit line capping pattern includes a seam therein.

13. A semiconductor device, comprising:
a first active pattern including a first edge portion and a second edge portion, which are spaced apart from each other in a first direction;
a first word line between the first edge portion of the first active pattern and the second edge portion of the first active pattern and extending in a second direction that crosses the first direction;
a first bit line on the first edge portion of the first active pattern and extending in a third direction that crosses the first and second directions; and
a storage node contact on the second edge portion of the first active pattern,
wherein the first bit line is offset from the second edge portion in the second direction, and at a level higher than the second edge portion of the first active pattern.

14. The semiconductor device as claimed in claim 13, wherein the first bit line is in contact with the first edge portion of the first active pattern.

15. The semiconductor device as claimed in claim 13, further comprising a second bit line, which is adjacent to the first bit line in the second direction,
wherein a distance between the first bit line and the second bit line is larger than a width of the second edge portion of the first active pattern, when measured in the second direction.

16. The semiconductor device as claimed in claim 13, further comprising:
a second bit line, which is adjacent to the first bit line in the second direction; and
a bit line trench region defined by the first bit line and the second bit line,
wherein the bit line trench region is vertically overlapped with the second edge portion of the first active pattern.

17. The semiconductor device as claimed in claim 13, further comprising:
a second active pattern, which is adjacent to the first active pattern in the second direction;
a third active pattern, which is adjacent to the second active pattern in the third direction; and
a fourth active pattern, which is adjacent to the first active pattern in the third direction,
wherein a second edge portion of the fourth active pattern, the first edge portion of the first active pattern, a second edge portion of the third active pattern, and a first edge portion of the second active pattern are disposed, in the order enumerated, in the second direction.

18. The semiconductor device as claimed in claim 17, further comprising a second word line, which is adjacent to the first word line in the third direction,
wherein:
the first word line crosses the first active pattern and the second active pattern, and
the second word line crosses the third active pattern and the fourth active pattern.

19. A semiconductor device, comprising:
an active pattern including a first edge portion and a second edge portion, which are spaced apart from each other in a first direction;
a word line between the first edge portion of the active pattern and the second edge portion of the active pattern and extending in a second direction that crosses the first direction;
a bit line on the first edge portion of the active pattern and extending in a third direction that crosses the first and second directions; and
a storage node contact on the second edge portion of the active pattern,
wherein the bit line is in contact with the first edge portion of the active pattern.

20. The semiconductor device as claimed in claim 19, wherein a top surface of the first edge portion is at a level higher than a bottom end of the storage node contact.
